(19) United States
(12) Patent Application Publication
(10) Pub. No.: US 2025/0183869 A1
(43) Pub. Date: Jun. 5, 2025

(54) COMPOSITE SUBSTRATE, ACOUSTIC WAVE ELEMENT, MODULE, AND COMMUNICATION DEVICE

(71) Applicant: KYOCERA Corporation, Kyoto-shi, Kyoto (JP)

(72) Inventor: Tomio KANAZAWA, Daito-shi (JP)

(73) Assignee: KYOCERA Corporation, Kyoto-shi, Kyoto (JP)

(21) Appl. No.: 18/843,282

(22) PCT Filed: Mar. 1, 2023
(86) PCT No.: PCT/JP2023/007485

§ 371 Date: Sep. 2, 2024

(30) Foreign Application Priority Data
Mar. 2, 2022 (JP) 2022-031421

(51) Int. Cl. H03H 9/02; H03H 9/145; H03H 9/25; H03H 9/64

(52) U.S. Cl. CPC H03H 9/02574; H03H 9/02559; H03H 9/02866; H03H 9/02992; H03H 9/145; H03H 9/25; H03H 9/6483

(57) ABSTRACT

A composite substrate includes a piezoelectric layer and a low-acoustic-velocity film. The low-acoustic-velocity film extends along a bottom surface of the piezoelectric layer and has a lower acoustic velocity than the piezoelectric layer. An inverse velocity plane of an acoustic wave propagating through the piezoelectric layer is concave.

### TECHNICAL FIELD

The present disclosure relates to a composite substrate and an acoustic wave element including the composite substrate, and relates to a module and a communication device including the acoustic wave element.

### BACKGROUND OF INVENTION

An acoustic wave element includes, for example, a piezoelectric substrate having piezoelectricity at least at a top surface thereof and an IDT (interdigital transducer) electrode located on the top surface of the piezoelectric substrate. Acoustic waves that propagate through the piezoelectric substrate are generated by a voltage being applied to the piezoelectric substrate by the IDT electrode.

Patent Literature 1 discloses, as a piezoelectric substrate, a composite substrate including a piezoelectric layer, a low-acoustic-velocity film stacked on a bottom surface of the piezoelectric layer, and a high-acoustic-velocity film stacked on a bottom surface of the low-acoustic-velocity film. In Patent Literature 1, the low-acoustic-velocity film is composed of a material in which bulk waves propagate at a lower acoustic velocity than acoustic waves propagating through the piezoelectric layer. The high-acoustic-velocity film is composed of a material in which bulk waves propagate at a higher acoustic velocity than acoustic waves propagating through the piezoelectric layer.

Patent Literature 1 discloses that an inverse velocity plane is convex in the composite substrate as described above (see paragraph 0039 of Patent Literature 1). The inverse velocity plane will be discussed later along with the description of embodiments of the present disclosure.

### CITATION LIST

### Patent Literature

Patent Literature 1: Japanese Unexamined Patent Application Publication No. 2019-80093

### SUMMARY

In an embodiment of the present disclosure, a composite substrate includes a piezoelectric layer and a low-acoustic-velocity film. The low-acoustic-velocity film extends along a bottom surface of the piezoelectric layer and has a lower acoustic velocity than the piezoelectric layer. An inverse velocity plane of an acoustic wave propagating through the piezoelectric layer is concave.

In an embodiment of the present disclosure, an acoustic wave element includes the composite substrate and a first IDT electrode. The first IDT electrode includes multiple electrode fingers arranged along a top surface of the piezoelectric layer.

In an embodiment of the present disclosure, a module includes the acoustic wave element, an antenna, and an integrated circuit element. The antenna is connected to the acoustic wave element. The integrated circuit element is connected to the antenna via the acoustic wave element.

In an embodiment of the present disclosure, a communication device includes the acoustic wave element, an antenna, an integrated circuit element, and a housing. The antenna is connected to the acoustic wave element. The integrated circuit element is connected to the antenna via the acoustic wave element. The housing houses the acoustic wave element and the integrated circuit element.

### BRIEF DESCRIPTION OF THE DRAWINGS

FIG. 1 is a plan view illustrating the configuration of main components of an acoustic wave element according to a First Embodiment.

FIG. 2 is a sectional view taken along line II-II in FIG. 1.

FIG. 3 is a sectional view taken along line III-III in FIG. 1.

FIG. 4 is a diagram illustrating an example of frequency characteristics of the acoustic wave element.

FIG. 5 is a schematic diagram for explaining a method for identifying acoustic velocity in various directions.

FIG. 6 is a diagram illustrating examples of inverse velocity planes for cases where the normalized thicknesses of piezoelectric layers are different from each other.

FIG. 7 is a diagram illustrating examples of inverse velocity planes for cases where the normalized thicknesses of low-acoustic-velocity films are different from each other.

FIG. 8 is a diagram illustrating examples of inverse velocity planes for cases where the cut angles of piezoelectric layers are different from each other.

FIG. 9 is a diagram illustrating the relationship between a parameter relating to the configuration of a composite substrate and a coefficient relating to an inverse velocity plane in the First Embodiment.

FIG. 10 is a diagram illustrating the relationship between a parameter relating to the configuration of the composite substrate and a coefficient relating to an inverse velocity plane in the First Embodiment.

FIG. 11 is a sectional view illustrating the configuration of an acoustic wave element according to a Second Embodiment.

FIG. 12 is a diagram illustrating the relationship between a parameter relating to the configuration of a composite substrate and a coefficient relating to an inverse velocity plane in the Second Embodiment.

FIG. 13 is a plan view illustrating the configuration of an acoustic wave element according to a First Variation.

FIG. 14 is a schematic diagram for describing an acoustic wave element according to a Second Variation.

FIG. 15 is a circuit diagram schematically illustrating the configuration of a splitter.

FIG. 16 is a block diagram schematically illustrating the configuration of a communication device.

### DESCRIPTION OF EMBODIMENTS

Hereafter, embodiments of the present disclosure will be described while referring to the drawings. The drawings are schematic drawings and the shapes and/or dimensions etc. in the drawings do not necessarily match the actual shapes and/or dimensions etc. However, the actual shapes and/or dimensions etc. may be as illustrated in the drawings, or features such as shapes and/or dimensions may be extracted from the drawings.

In the description of aspects described relatively later (embodiments and variations), basically, only the differences from the previously described aspects will be described. Matters not specifically mentioned may be assumed to be the same as or similar to those in previously described aspects or may be inferred from the previously described aspects. The descriptions of previously described aspects may be applied to later described aspects so long as no contradictions arise etc. In multiple aspects, components that correspond to each other may be denoted by the same symbols even if there are differences for the sake of convenience.

### First Embodiment

### Overview of Embodiment

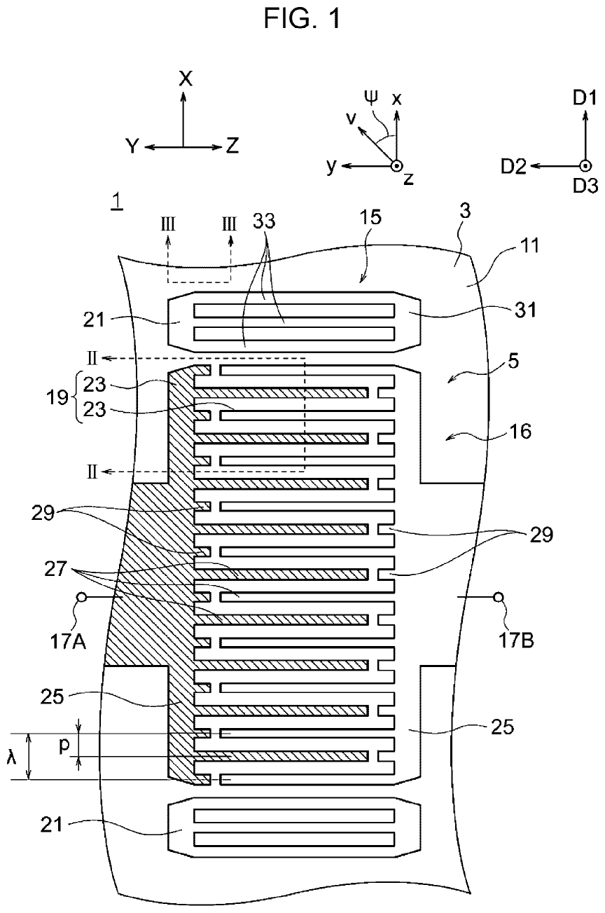

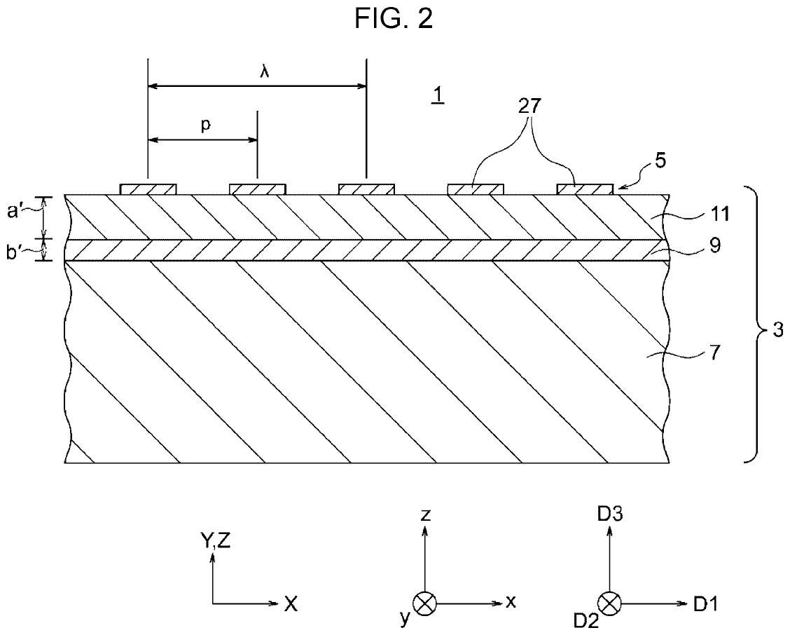

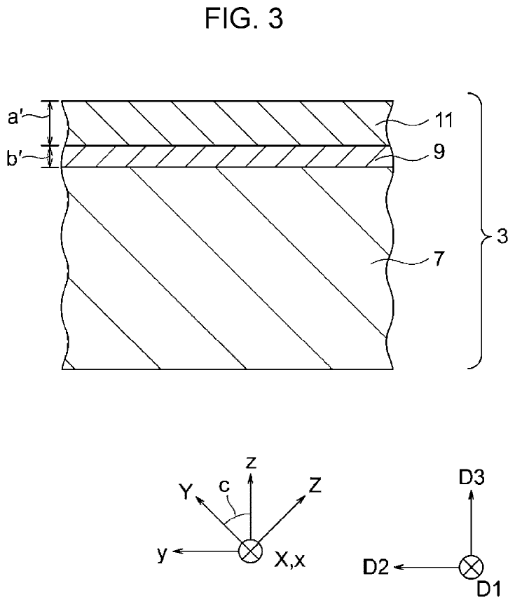

FIG. 1 is a plan view illustrating the configuration of main components of an acoustic wave element 1 according to a First Embodiment. FIG. 2 is a sectional view taken along line II-II in FIG. 1. FIG. 3 is a sectional view taken along line III-III in FIG. 1.

Any direction may be regarded as up or down with respect to the acoustic wave element 1. However, hereafter, for convenience, the front side of the sheet of FIG. 1 will be regarded as the front side and terms such as top surface and bottom surface may be used.

The acoustic wave element 1 includes, for example, a composite substrate 3 and a conductor layer 5 positioned on the composite substrate 3 (FIGS. 1 and 2). The composite substrate 3 includes, for example, a support substrate 7 (FIGS. 2 and 3), a low-acoustic-velocity film 9 (FIGS. 2 and 3) positioned on the support substrate 7, and a piezoelectric layer 11 positioned on the low-acoustic-velocity film 9. The acoustic velocity in the low-acoustic-velocity film 9 is lower than the acoustic velocity in the piezoelectric layer 11.

An electrical signal flowing through the conductor layer 5 is converted into acoustic waves that propagate through the piezoelectric layer 11. The acoustic waves that propagate through the piezoelectric layer 11 are converted into an electrical signal that flows through the conductor layer 5. Resonance and/or filtering of the electrical signal is realized, for example, by utilizing the resonance of the acoustic waves. The low-acoustic-velocity film 9, for example, contributes to reflecting the acoustic waves and confining the energy of the acoustic waves to the piezoelectric layer 11. The support substrate 7, for example, contributes to reinforcing the strength of the composite substrate 3.

A Cartesian coordinate system XYZ illustrates an example of the orientation of crystal axes in the piezoelectric layer 11. That is, the X axis, the Y axis, and the Z axis represent the crystal axes. A Cartesian coordinate system xyz illustrates the relationship between the piezoelectric layer 11 and the propagation direction of acoustic waves that are intended to be utilized. Specifically, the z direction is parallel to a normal of the top surface of the piezoelectric layer 11. The x direction is the propagation direction of acoustic waves that are intended to be utilized. The y direction is a direction parallel to the top surface of the piezoelectric layer 11 and perpendicular to the x direction. For convenience, the term acoustic waves may refer to acoustic waves that are intended (acoustic waves propagating in the x direction) to be utilized without any particular mention.

As can be understood from the relationship between the Cartesian coordinate system XYZ and the Cartesian coordinate system xyz, the piezoelectric layer 11 is composed of, for example, a so-called rotated Y-cut X-propagation piezoelectric single crystal. Therefore, the X axis and the x axis are parallel to each other. In addition, as illustrated in FIG. 3, the Y axis is inclined at a cut angle c° with respect to the normal (z axis) of the piezoelectric layer 11.

As illustrated in FIG. 1, v is the velocity (phase velocity) of acoustic waves propagating in a direction inclined at an angle ψ around the z-axis with respect to the x-axis. The velocity v depends on the angle ψ. That is, the velocity v is a function of ψ and can be expressed as v(ψ). The inverse of the velocity v, 1/v (or 1/v(ψ)), is called the inverse velocity (or slowness). Although not particularly illustrated, the inverse velocity 1/v can be broken down into a component 1/vₓ in the x direction and a component 1/v_{y} in the y direction. 1/vₓ=1/v×cos ψ and 1/v_{y}=1/v×sin ψ. (1/v_{y})/(1/vₓ)=tan ψ.

A value obtained by dividing the inverse velocity 1/v(ψ) by the inverse velocity 1/v(0) for ψ=0° will be referred to as a normalized inverse velocity 1/vₙ (or 1/vₙ(ψ)). The x-direction component and the y-direction component of the normalized inverse velocity 1/vₙ will be denoted as 1/vₙₓ and 1/v_{ny}. Similarly to the non-normalized inverse velocity, 1/vₙₓ=1/vₙ×cos ψ, 1/v_{ny}=1/vₙ×sin ψ, and (1/v_{ny})/(1/vₙₓ)=tan ψ. For ψ=0°, 1/vₙₓ=1 and 1/v_{ny}=0.

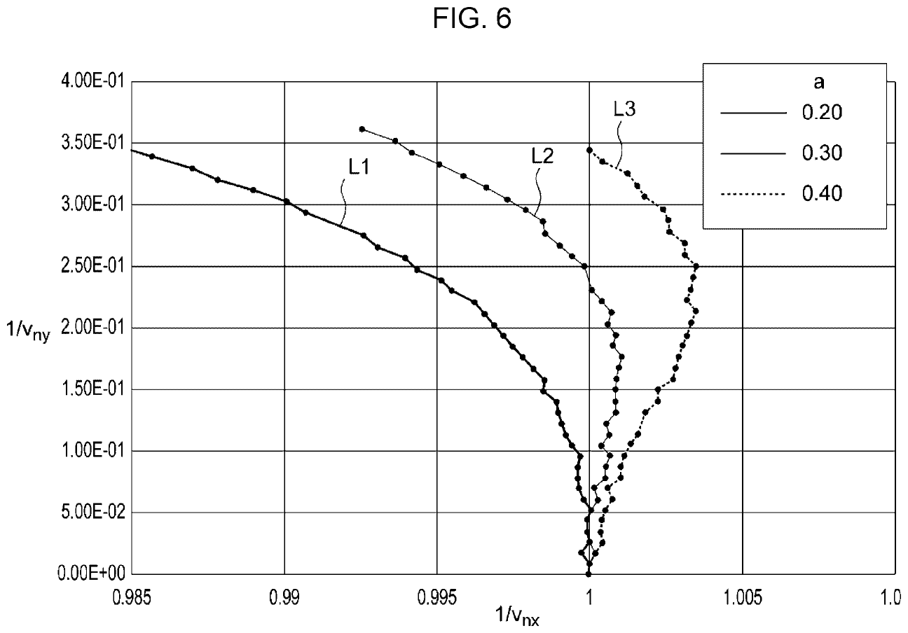

FIG. 6 illustrates examples of the normalized inverse velocity 1/vₙ(ψ) of acoustic waves propagating through the piezoelectric layer 11 in the composite substrate 3. In this figure, the horizontal axis represents an x-direction component 1/vₙₓ of the normalized inverse velocity. The vertical axis represents a y-direction component 1/v_{ny} of the normalized inverse velocity. Lines L1 to L3 represent the normalized inverse velocities in three examples. The three examples differ from each other with respect to a thickness a of the piezoelectric layer 11 (FIGS. 2 and 3).

Taking the line L1, among the lines L1 to L3, as an example, the line L1 represents the normalized inverse velocity 1/vₙ (ψ) when w is varied. The intersection of the line L1 with the horizontal axis ((1/vₙₓ, 1/vₙₓ)=(1, 0)) corresponds to the inverse velocity at ψ=0°. The line L1 extends away from the intersection as ψ increases from 0° and is a curved line in the illustrated example. As is understood from the ratio of 1/vₙₓ to 1/v_{ny} at the ends of the lines L1 to L3 where ψ is large (=tan ψ), FIG. 6 schematically illustrates the normalized inverse velocity 1/vₙ(ψ) when ψ is greater than or equal to 0° and less than or equal to 20°.

Each of these lines L1 to L3 is an example of an “inverse velocity plane (or inverse velocity curved plane)”. In other words, “inverse velocity plane” refers to a line obtained by plotting the normalized inverse velocity 1/vₙ(ψ) (or an equivalent physical quantity) while varying v on a plane with 1/vₙₓ and 1/v_{ny} (or equivalent physical quantities) serving as two axes (horizontal and vertical) that are perpendicular to each other. As is clear from FIG. 6, the ratio of 1/vₙₓ to a predetermined length on the sheet and the ratio of 1/v_{ny} to the predetermined length on the sheet may be the same as or different from each other.

Although not specifically illustrated, a line representing the normalized inverse velocity 1/vₙ(ψ) when w is reduced from 0° (i.e., when the absolute value is increased on the negative side), for example (or in general), has a shape that is line symmetric with respect to the shape of the illustrated line (ψ>0°) in a range centered on the horizontal axis (ψ=0°) (e.g. −15°<ψ<15°) with the horizontal axis serving as the axis of symmetry. In the description of the embodiments, for convenience, although only the range of ψ>0° is illustrated, the range of ψ<0° is sometimes described as though also illustrated. For convenience, the description may be given taking only ψ>0° (or, from another perspective, the +1/v_{ny} side) as an example, or the description may be given without distinguishing between ψ>0° and ψ<0° (or, from another perspective, the +1/v_{ny} and −1/v_{ny} sides), without any particular mention.

In addition, an inverse velocity plane in a range centered on ψ=180° (e.g., 165°<ψ<195°), for example (or in general), has a similar shape (but the positive and negative values of 1/vₓ are reversed) as an inverse velocity plane in a range centered on ψ=0° (e.g., −15°<ψ<15°). Hereafter, for convenience, the description may be given taking only the inverse velocity plane in the vicinity of ψ=0° (or +1/vₓ side from another perspective) as an example, or the description may be given without distinguishing between ψ=0° and ψ=180° (or +1/vₓ side and −1/vₓ side from another perspective) without any particular mention.

The line L1 is an example of a so-called convex inverse velocity plane. The lines L2 and L3 are examples of so-called concave inverse velocity planes. As can be understood from comparing the former and the latter, a convex inverse velocity plane generally has a convex shape with the inverse velocity at ψ=0° being at the apex (or, from another perspective, the intersection with the horizontal axis) in a range centered on ψ=0° (e.g., −15°<ψ<15°). On the other hand, a concave inverse velocity plane generally has a concave shape with the inverse velocity at ψ=0° being the lowest in a range centered on ψ=0°. In the illustrated range (generally −20°<ψ<20°), the concave inverse velocity planes (lines L2 and L3) in the examples may be viewed as a convex shape having a recessed top.

From another point of view, when a convex inverse velocity plane appears, in a range centered on ψ=0° (e.g. −15°<ψ<15°), basically, the absolute value of 1/vₙₓ becomes smaller and the absolute value of 1/v_{ny} becomes larger as the absolute value of ψ increases from 0°. When a concave inverse velocity plane appears, basically, the absolute value of 1/vₙₓ becomes larger and the absolute value of 1/v_{ny} becomes larger as the absolute value of ψ increases from 0° in a range centered on ψ=0°. In the illustrated range (approximately −20°<ψ<20°), the absolute value of 1/vₙₓ begins to decrease as the absolute value of ψ increases further.

Inverse velocity planes span from 0° to 360°. However, when an inverse velocity plane is said to be concave or convex in the description of this embodiment, this means that the inverse velocity plane has a concave or convex shape, generally centered on ψ=0°, as described above. In other words, the inverse velocity planes focused on in this embodiment have a relatively narrow range substantially centered at ψ=0°. The relatively narrow range is, for example, −15°<ψ<15° or −10°<ψ<10°. The reason why the expression a range “substantially” centered at ψ=0° is that the center of a concave shape or a convex shape and the x direction (direction of ψ=0°) do not necessarily need to coincide with each other. For example, they may be shifted from each other by less than 5°. Of course, such deviations may exist as a tolerance.

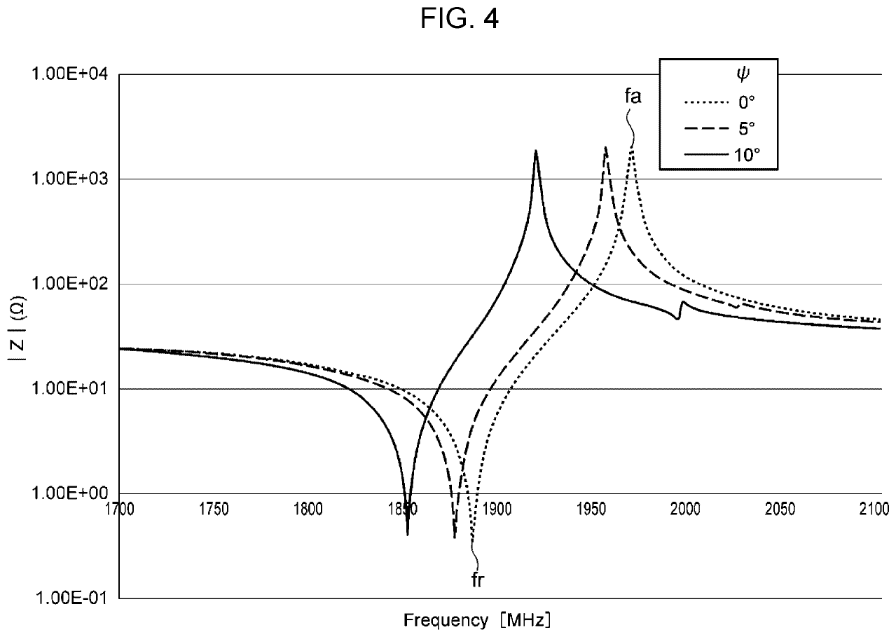

As a result of diligent studies, the inventors of the present application found that not only convex inverse velocity planes but also concave inverse velocity planes can be realized in the composite substrate 3 having the structure illustrated in FIGS. 2 and 3. A concave inverse velocity plane reduces the probability of spurious being generated between a resonance frequency fr (FIG. 4) and an anti-resonance frequency fa (FIG. 4), as described below, compared with, for example, a convex inverse velocity plane.

More precisely, for example, a concave inverse velocity plane is realized when the following Equation (1) is satisfied.

$$- 3.36797 a + 2.582139 {a}^{2} - 1.02894 b + 1.487276 {b}^{2} - 0.02411 c + 0.000309 {c}^{2} + 0.432673 ab - 0.00517 ac + 0.000873 bc + 0.272652 < - 1 \qquad ( 1 )$$

Here, a is the normalized thickness of the piezoelectric layer 11, which is a value obtained by dividing a thickness a′ (μm) of the piezoelectric layer 11 by the wavelength λ (μm) of the acoustic waves. b is the normalized thickness of the low-acoustic-velocity film 9, which is a value obtained by dividing a thickness b′ (μm) of the low-acoustic-velocity film 9 by the wavelength λ (μm). c is the cut angle (°) as described previously.

An overview of the First Embodiment has been described above. Hereafter, the First Embodiment will be briefly described in the following order.
1. Composite Substrate 3 (except for configuration for realizing concave inverse velocity plane)
1.1. Piezoelectric Layer 11
1.2. Low-Acoustic-Velocity Film 9
1.3. Support Substrate 7
2. Conductor Layer 5
2.1. IDT electrode
2.2. Reflectors
3. Rest of Configuration of Acoustic Wave Element
4. Operation and Characteristics of Acoustic Wave Element (FIG. 4)
5. Configuration for Realizing Concave Inverse Velocity Plane (FIGS. 4 to 10)
5.1 Method for Identifying Inverse Velocity Plane
5.2. Example of Simulation Calculations
5.3. Equation Representing Conditions Under Which Inverse Velocity Plane is Realized
5.4. Examination of Conditions Under Which Inverse Velocity Plane Is Realized
6. Summary of First Embodiment

### 1. Composite Substrate

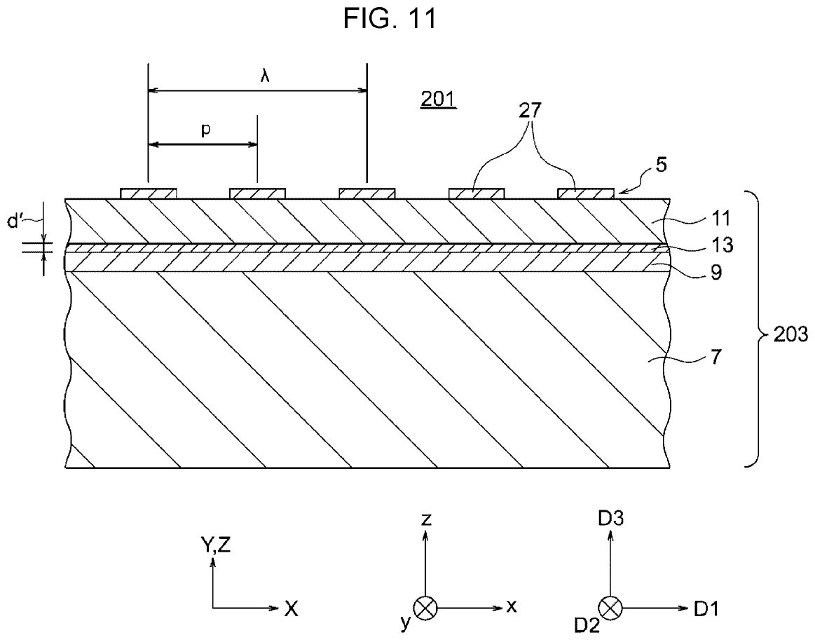

As previously described, the composite substrate 3 includes the piezoelectric layer 11, the low-acoustic-velocity film 9, and the support substrate 7, which are stacked on each other from the top in this order. In this embodiment, these layers are directly stacked on each other from an acoustic point of view. In other words, there are no layers (for example, a high-acoustic-velocity film 13 (FIG. 11) in a Second Embodiment described below) interposed between these layers that has an acoustic effect on the acoustic waves propagating through the piezoelectric layer 11.

When two layers are described as being directly stacked on each other from an acoustic point of view as above, when examined more closely, there may be another layer interposed between the two layers that has little or no acoustic effect on the acoustic waves propagating through the piezoelectric layer 11. The other layer may be, for example, a bonding layer that contributes to the bonding of the two layers. Whether or not two layers are directly stacked on each other from an acoustic point of view may be reasonably determined in light of technical common sense and so on. The other layer mentioned above (e.g., a bonding layer) is, for example, of such a thickness as to have little acoustic effect on the acoustic waves propagating through the piezoelectric layer 11. Such a thickness depends on the material of the other layers, etc., but a specific example may be 0.005λ or less or 0.001λ or less. In the description of the embodiments, the presence of a bonding layer is basically ignored.

The acoustic waves that are intended to be utilized in the acoustic wave element 1 and that propagate through the piezoelectric layer 11 may be any suitable acoustic waves. For example, the acoustic waves may be surface acoustic waves, bulk waves, plate waves (Lamb waves), or might not be distinguishable in the manner described above. The acoustic waves utilized depend on, for example, the material, the cut angle (not necessarily the cut angle c previously described), and the thickness of the piezoelectric layer 11, the configuration of the side below the piezoelectric layer 11 (configuration of the low-acoustic-velocity film 9, etc.) and the configuration of the side above the piezoelectric layer 11 (configuration of the conductor layer 5, etc.).

### (1.1. Piezoelectric Layer)

The piezoelectric layer 11 is composed of, for example, a single crystal having piezoelectricity. For example, lithium tantalate (LiTaO₃, hereinafter may be abbreviated as LT), lithium niobate (LiNbO₃, hereinafter may be abbreviated as LN), and quartz (SiO₂) are examples of the material constituting such a single crystal. The piezoelectric layer 11 may be composed of a polycrystalline material.

The material, cut angle, and thickness of the piezoelectric layer 11 affect the realization of a concave inverse velocity plane. In this embodiment, an example in which the material of the piezoelectric layer 11 is rotated Y-cut X-propagation LT is described, and the specific values of the cut angle and thickness with which a concave inverse velocity plane is realized are described. However, as described below, even when the material of the piezoelectric layer 11 is a material other than rotated Y-cut X-propagation LT, a concave inverse velocity plane can be realized by appropriately setting the cut angle and thickness of the piezoelectric layer 11 and the conditions of the other layers.

The cut angle c and the normalized thickness a of the piezoelectric layer 11 may be set to values that satisfy Equation (1) as previously described. When Equation (1) is satisfied or not satisfied, the lower limit and upper limit of the normalized thickness a when realizing a concave inverse velocity plane may be set as appropriate. For example, the normalized thickness a may be greater than or equal to 0.05 or greater than or equal to 0.1. With such a thickness, for example, acoustic waves propagating through the piezoelectric layer 11 can be used. For example, the normalized thickness a may be greater than or equal to 0.2 or greater than or equal to 0.3. The inventors of the present application confirmed that a concave inverse velocity plane can be realized at such thicknesses, as illustrated by the simulation results described below and so on (FIGS. 6 to 10). For example, the normalized thickness a may be less than or equal to 1.0. In this case, if anisotropy is ignored, a boundary condition is defined by positioning the layer stacked on the bottom surface of the piezoelectric layer 11 (low-acoustic-velocity film 9 in this embodiment) within one wavelength of the vibration excited at the top surface of the piezoelectric layer 11 and propagating downward. Therefore, the characteristics of the multilayer structure of the piezoelectric layer 11 and the low-acoustic-velocity film 9 are likely to appear. For example, the normalized thickness a may be less than or equal to 0.6. The inventors of the present application confirmed that a concave inverse velocity plane can be realized at such thicknesses, as illustrated by the simulation results described below and so on (FIGS. 6 to 10). The lower and upper limits already mentioned may be combined with each other in any manner.

### (1.2. Low-Acoustic-Velocity Film)

The low-acoustic-velocity film 9 extends along the bottom surface of the piezoelectric layer 11. When described in this manner, the low-acoustic-velocity film 9 may be directly stacked on the bottom surface of the piezoelectric layer 11 from an acoustic point of view (as in this embodiment) or indirectly stacked on the bottom surface of the piezoelectric layer 11 from an acoustic point of view, as in the Second Embodiment (see FIG. 11), which is described below.

The material of the low-acoustic-velocity film 9 may be any material so long as the acoustic velocity in the low-acoustic-velocity film 9 is lower than the acoustic velocity in the piezoelectric layer 11. Physical properties (density, Young's modulus, acoustic impedance, etc.) that have an effect on acoustic velocity may also be set to any values.

The acoustic velocities in the comparison of the acoustic velocity in the low-acoustic-velocity film 9 and the acoustic velocity in the piezoelectric layer 11 may be, for example, the acoustic velocities of bulk waves propagating through the respective layers. Generally speaking, bulk waves include three types of waves, namely, longitudinal waves, slow transverse waves, and fast transverse waves. Slow transverse waves or fast transverse waves are for example either SV (shear vertical) waves or SH (shear vertical) waves. The bulk waves used in the comparison may be, for example, bulk waves corresponding to a component that propagates through the piezoelectric layer 11 and is primarily included in the acoustic waves that are intended to be used among of the above three types of bulk waves. This is because the low-acoustic-velocity film 9 is expected to confine the acoustic waves propagating through the piezoelectric layer 11, as already mentioned. For example, if the acoustic waves in the piezoelectric layer 11 intended to be utilized primarily contain SH waves, the acoustic velocity of the SH waves in the piezoelectric layer 11 may be compared to the acoustic velocity of the SH waves in the low-acoustic-velocity film 9. SH waves were taken as an example, but the same applies to SV waves or longitudinal waves. If acoustic waves that are combination of longitudinal waves and transverse waves are intended to be used, for example, the acoustic velocity of the transverse waves may be compared.

The conditions for comparison need not necessarily be as strict as those described above. From another perspective, in the comparison of the acoustic velocity in the piezoelectric layer 11 and the acoustic velocity in the low-acoustic-velocity film 9, the two acoustic velocities do not need to be strictly identified. For example, when comparing the transverse acoustic velocity of the low-acoustic-velocity film 9 and the transverse acoustic velocity of the piezoelectric layer 11, even if the difference between fast transverse waves and slow transverse waves in the low-acoustic-velocity film 9 is relatively small (the difference between the transverse acoustic velocity of the low-acoustic-velocity film 9 and the transverse acoustic velocity of the piezoelectric layer 11 is relatively large) and there is no particular need to distinguish between fast transverse waves and slow transverse waves in the low-acoustic-velocity film 9, there is no need to distinguish between fast and slow transverse acoustic waves in the low-acoustic-velocity film 9 when the transverse acoustic velocity of the low-acoustic-velocity film 9 is clearly lower than the transverse wave acoustic velocity of the piezoelectric layer 11. From another perspective, components that are mainly contained by the acoustic waves of the piezoelectric layer 11 that are intended to be utilized do not need to be strictly identified.

The acoustic velocity in the piezoelectric layer 11 depends on, for example, the direction in which the acoustic velocity is identified (w from another perspective), as well as the cut angle and thickness of the piezoelectric layer 11, as understood from the previous description of the inverse velocity plane, and is also affected by the layer below the piezoelectric layer 11 (here, the low-acoustic-velocity film 9). This similarly applies to the low-acoustic-velocity film 9. Therefore, when comparing the acoustic velocities in two layers (here, the piezoelectric layer 11 and the low-acoustic-velocity film 9), the relationship between the high and low acoustic velocities of the two layers may differ depending on what conditions are used for the comparison. Therefore, when the acoustic velocities in two layers are compared, for example, the acoustic velocities in the x direction in two layers within the composite substrate 3 having the same configuration as the actual product may be compared. In other words, specific acoustic velocities may be compared while taking into account the effects of specific cut angles, thicknesses, and so on.

However, the effects of the cut angle, thickness, and so on do not necessarily need to be taken into account. From another perspective, in a comparison of the acoustic velocities in two layers (here, the piezoelectric layer 11 and the low-acoustic-velocity film 9), the acoustic velocities of the two layers do not need to be strictly identified. For example, the acoustic velocity in the x direction of the low-acoustic-velocity film 9 in the actual product does not need to be identified when the acoustic velocity in the low-acoustic-velocity film 9 is clearly lower than the acoustic velocity in the piezoelectric layer 11, regardless of the cut angle and/or thickness of the piezoelectric layer 11 and the thickness of the low-acoustic-velocity film 9. In such cases, acoustic velocities may be calculated and compared using a simple theoretical formula based on density and Young's modulus, etc.

As will be clear from the description of an example of a resonator using a piston mode described below, the velocity of acoustic waves is also affected by the conductor layer 5, etc. positioned on the piezoelectric layer 11, and also differs in each region of the acoustic wave element 1. In the comparison of acoustic velocities in two layers (here, the piezoelectric layer 11 and the low-acoustic-velocity film 9), for example, the average acoustic velocity in a crossing region CR (see below) in the acoustic wave element 1 having the same configuration as the actual product may be used. However, for example, if the acoustic velocity in the low-acoustic-velocity film 9 is clearly lower than the acoustic velocity in the piezoelectric layer 11, regardless of the effect of the conductor layer 5, etc., or if the acoustic velocity in the low-acoustic-velocity film 9 is clearly lower than the acoustic velocity in the piezoelectric layer 11 in the same region in a planar perspective view, the acoustic velocities in such crossing regions do not need to be strictly determined.

For example, silicon dioxide (SiO₂), tantalum oxide (Ta₂O₃), silicon oxynitride (Si₂N₂O), and glass may be given as examples of specific materials of the low-acoustic-velocity film 9. Compounds obtained by adding fluorine, carbon, boron or the like to SiO₂ may also be used. The various materials listed for the piezoelectric layer 11 (e.g., LT and LN) may be combined with any of the materials listed here. The conditions used when comparing the acoustic velocity in the piezoelectric layer 11 with the acoustic velocity in the low-acoustic-velocity film 9 have been described in detail. However, if the material of the low-acoustic-velocity film 9 is any of the materials listed in this paragraph, some or all of the previously described conditions for comparison may be ignored.

The material and thickness of the low-acoustic-velocity film 9 affect the realization of a concave inverse velocity plane. In this embodiment, an example in which the material of low-acoustic-velocity film 9 is SiO₂ is described, and the specific value of the thickness that allows a concave inverse velocity plane to be realized is described. However, as described below, even when the material of low-acoustic-velocity film 9 is a material other than SiO₂, a concave inverse velocity plane can be realized by setting the thickness of low-acoustic-velocity film 9 and the conditions of other layers as appropriate.

A normalized thickness b of the low-acoustic-velocity film 9 may be a value that satisfies Equation (1), as previously described. When Equation (1) is satisfied or not satisfied, the lower limit and upper limit of the normalized thickness b when realizing a concave inverse velocity plane may be set as appropriate. For example, the thickness of the low-acoustic-velocity film 9 may be greater than or equal to 0.01 or greater than or equal to 0.1, and less than or equal to 0.6 or less than or equal to 0.5. The lower and upper limits may be combined with each other in any manner. The inventors of the present application confirmed that a concave inverse velocity plane can be realized at such thicknesses, as illustrated by the simulation results described below and so on (FIGS. 6 to 10).

### (1.3. Support Substrate)

The material and dimensions of the support substrate 7 may be freely chosen. Since acoustic waves propagating through the piezoelectric layer 11 are essentially reflected by the low-acoustic-velocity film 9, the material and dimensions of the support substrate 7 have relatively little direct effect on the acoustic waves propagating through the piezoelectric layer 11. The inventors of the present application confirmed through simulation calculations that the support substrate 7 has little effect on whether the inverse velocity plane is concave or convex.

The material of the support substrate 7 may have a lower coefficient of thermal expansion than the piezoelectric layer 11, etc. In this case, for example, the risk of the frequency characteristics of the acoustic wave element 1 changing due to changes in temperature can be reduced. For example, a semiconductor such as silicon (Si), a single crystal such as sapphire, and a ceramic such as sintered aluminum oxide can be used as such a material. The support substrate 7 may include multiple layers composed of different materials stacked on top of each other. The thickness of the support substrate 7 is, for example, greater than that of the piezoelectric layer 11.

### 2. Conductor Layer

The conductor layer 5 is formed using a metal, for example. The specific type of metal may be freely chosen. For example, the metal may be aluminum (Al) or an alloy having Al as a main component (Al alloy). The Al alloy may be, for example, an aluminum-copper (Cu) alloy. The conductor layer 5 may include multiple metal layers. For example, a relatively thin layer composed of titanium (Ti) may be provided between the Al or Al alloy and the piezoelectric layer 11 in order to strengthen the bond therebetween. The thickness of the conductor layer 5 may be appropriately set in accordance with the characteristics required for the acoustic wave element 1. For example, the thickness of the conductor layer 5 may be greater than or equal to 0.02λ and less than or equal to 0.10λ and/or greater than or equal to 50 nm and less than or equal to 600 nm.

The conductor layer 5 includes an IDT electrode 19 and a pair of reflectors 21 positioned on both sides of the IDT electrode 19, as illustrated in FIG. 1.

The regions of the composite substrate 3 and the conductor layer 5 where the IDT electrode 19 and the pair of reflectors 21 are positioned constitute a resonator 15. The resonator 15 is configured as a so-called one-port acoustic wave resonator. For example, when an electrical signal of a prescribed frequency is input from one of terminals 17A and 17B, which are conceptually and schematically illustrated, resonance is generated and a signal that generated the resonance can be output from the other of the terminals 17A and 17B.

The resonator 15 includes at least part of the top surface side of the composite substrate 3 as well as the IDT electrode 19 and the pair of reflectors 21, as described above. The at least part of mentioned here includes, for example, the piezoelectric layer 11 and the low-acoustic-velocity film 9. In the description of the embodiments, for convenience, the resonator 15 may be represented as though consisting of only the IDT electrode 19 and the pair of reflectors 21 (the configuration excluding the composite substrate 3). The region of the resonator 15 where the IDT electrode 19 is disposed (configuration excluding the regions where the reflectors 21 are positioned) is also a resonator. This resonator may sometimes be referred to as a resonator 16.

### (2.1. IDT Electrode)

The IDT electrode 19 includes a pair of comb electrodes 23. For better visibility, one of the comb electrodes 23 is shaded with hatching. Each comb electrode 23 includes, for example, a busbar 25, multiple electrode fingers 27 extending parallel to each other from the busbar 25, and dummy electrodes 29 protruding from the busbar 25 between the multiple electrode fingers 27. The pair of comb electrodes 23 are disposed so that the multiple electrode fingers 27 mesh with each other (cross each other).

Each busbar 25 is, for example, generally shaped so as to have a constant width and extend in a straight line in the propagation direction of acoustic waves (x direction). The pair of busbars 25 face each other in a direction that intersects the propagation direction of acoustic waves (y direction). Unlike in the illustrated example, the busbars 25 may vary in width or be inclined with respect to the propagation direction of acoustic waves.

Each of the electrode fingers 27 is, for example, generally shaped so as to have a constant width and extend in a straight line in a direction perpendicular to the propagation direction of acoustic waves (y direction). In each comb electrode 23, the multiple electrode fingers 27 are arranged in the propagation direction of acoustic waves (x direction). The multiple electrode fingers 27 of one comb electrode 23 and the multiple electrode fingers 27 of the other comb electrode 23 are basically arranged in an alternating manner with respect to each other.

A pitch p of the multiple electrode fingers 27 (for example, the distance between the centers of two adjacent electrode fingers 27) is basically constant within the IDT electrode 19. However, parts of the IDT electrode 19 may include narrow pitch portions where the pitch p is narrower than that in most other portions, or wide pitch portions where the pitch p is wider than that in most other portions. Furthermore, a thinned-out portion may exist in part of the IDT electrode 19 where the electrode fingers 27 are substantially thinned out.

In the description of the embodiments, the term pitch p refers to the pitch of the portions (the majority of the multiple electrode fingers 27) other than the above-mentioned narrow pitch portions, wide pitch portions, or special portions such as thinned-out portions, unless otherwise noted. In cases where the pitch varies even in the majority of the multiple electrode fingers 27 (for example, 80% or more of the electrode fingers 27), excluding the special portions, the average value of the pitch of the majority of the multiple electrode fingers 27 may be used as the value of the pitch p.

As will be understood from the following description, the pitch p may be set in accordance with the resonance frequency intended to be used. For example, the pitch p may be greater than or equal to 0.1 μm, 0.3 μm, or 0.5 μm, and less than or equal to 10 μm, 5 μm, or 2 μm. The lower and upper limits may be combined with each other in any manner.

The number of electrode fingers 27 may be set as appropriate in accordance with the electrical characteristics etc. required for the resonator 15. FIG. 1 is a schematic diagram, and therefore a small number of the electrode fingers 27 are illustrated. In reality, a greater number of electrode fingers 27 may be arranged than is illustrated in the figure. This is also true for strip electrodes 33 of the reflectors 21 described below.

The multiple electrode fingers 27 have the same lengths as each other, for example. Unlike in the illustrated example, the IDT electrode 19 may be so-called apodized so that the lengths (from another perspective, the so-called crossing widths) of the multiple electrode fingers 27 vary in accordance with their positions in the propagation direction of acoustic waves (x direction). The lengths and widths of the electrode fingers 27 may be set as appropriate in accordance with the required electrical characteristics, etc.

The dummy electrodes 29 are, for example, generally shaped so as to have a constant width and protrude in a direction perpendicular to the propagation direction of acoustic waves. This width is, for example, identical to the width of the electrode fingers 27. The multiple dummy electrodes 29 are arranged at the same pitch as the multiple electrode fingers 27, and the tips of the dummy electrodes 29 of one comb electrode 23 face the tips of the electrode fingers 27 of the other comb electrode 23 across a gap. Note that the IDT electrode 19 does not need to include the dummy electrodes 29.

### (2.2. Reflectors)

The pair of reflectors 21 are positioned on both sides of the IDT electrode 19 in the propagation direction of acoustic waves. Each reflector 21 may be electrically floating or supplied with a reference potential, for example. Each reflector 21 is formed in the shape of a lattice, for example. In other words, each reflector 21 includes a pair of busbars 31 facing each other and multiple strip electrodes 33 extending between the pair of busbars 31. The pitch of the multiple strip electrodes 33 and the pitch between each adjacent electrode finger 27 and strip electrode 33 are equivalent to the pitch of the multiple electrode fingers 27, for example.

### 3. Rest of Configuration of Acoustic Wave Element

Although not specifically illustrated, the top surface of the piezoelectric layer 11 may be covered by a protective film composed of SiO₂ and/or Si₃N₄ or the like from above the conductor layer 5. The protective film may, for example, contribute to reduction of corrosion of the conductor layer 5 and/or temperature compensation with respect to the characteristics of the acoustic wave element 1. When a protective film is provided, etc., an additional film composed of an insulator or metal may be provided on the top surface or bottom surface of the IDT electrode 19 and the reflectors 21. The additional film, for example, contributes to improvement of the reflection coefficient of acoustic waves.

The configuration illustrated in FIGS. 1 to 3 may be packaged as appropriate. The packaging may be, for example, packaging in which the illustrated configuration is mounted on a substrate, which is not illustrated, with the top surface of the piezoelectric layer 11 facing the substrate across a gap and then sealed with resin from above, or may be a wafer-level package type of packaging in which a box-type cover is provided above the piezoelectric layer 11.

In a form where multiple resonators 15 (or 16) are positioned on a single composite substrate 3, one resonator 15 may be regarded as one acoustic wave element 1, or multiple resonators 15 (corresponding to one composite substrate 3) may be regarded as one acoustic wave element 1. In the description of this embodiment, however, the term acoustic wave element 1 may refer to a single resonator 15 without any particular mention. In a form in which the composite substrate 3 and conductor layer 5 are packaged, the configuration including the package may be regarded as the acoustic wave element 1, or the configuration without the package may be regarded as the acoustic wave element 1.

### 4. Operation and Characteristics of Acoustic Wave Element

When a voltage is applied to the pair of comb electrodes 23, a voltage is applied to the piezoelectric layer 11 by the multiple electrode fingers 27 and the piezoelectric layer 11 vibrates. In other words, acoustic waves are excited. Among acoustic waves of various wavelengths propagating in various directions, acoustic waves propagating in the arrangement direction of the multiple electrode fingers 27 with the pitch p of the multiple electrode fingers 27 being approximately half the wavelength (2/2) tend to have a larger amplitude because multiple waves excited by the multiple electrode fingers 27 overlap in phase with each other. The acoustic waves propagating through the piezoelectric layer 11 are converted into an electrical signal by the multiple electrode fingers 27. At this time, similarly to as when the acoustic waves are excited, the strength of an electrical signal converted from acoustic waves propagating in the arrangement direction of the multiple electrode fingers 27 with the pitch p of the multiple electrode fingers 27 approximately half the wavelength (2/2) tends to be higher. As a result of the above operation (and other operations omitted here), the acoustic wave element 1 functions as a resonator whose resonance frequency is, for example, the frequency of an acoustic wave whose half wavelength is equal to the pitch p.

The pair of reflectors 21 reflects the acoustic waves and contributes to confining the energy to the region in which the IDT electrode 19 is disposed. However, even if the pair of reflectors 21 is not provided (even in the resonator 16), the above operation still occurs.

λ is a symbol that usually represents the wavelength. The actual wavelength of the acoustic waves may deviate from 2p. If the actual wavelength deviates from 2p, λ in the description of embodiments will refer to 2p, rather than the actual wavelength.

FIG. 4 is a diagram illustrating an example of the frequency characteristics of the acoustic wave element 1 (resonator 15).

In this figure, the horizontal axis represents frequency (MHz). The vertical axis represents the absolute value of impedance |Z| (Ω). The three lines in figure respectively represent the characteristics of three acoustic wave elements 1 (resonators 15). FIG. 4 is for describing the general characteristics of the resonator 15 having the configuration described thus far. In other words, the resonators 15 having the characteristics represented by the three lines are not necessarily examples, and may be comparative examples.

As illustrated in this figure, a resonance point fr, where the absolute value of the impedance is a minimum value, and an anti-resonance point fa, where the absolute value of the impedance is a maximum value, appear in the impedance characteristics of the resonators 15. The former frequency is the resonance frequency and the latter frequency is the anti-resonance frequency. In the description of the embodiments, the symbols fa and fr may be used to represent resonance frequencies and anti-resonance frequencies.

### 5. Configuration for Realizing Concave Inverse Velocity Plane

### (5.1 Method for Identifying Inverse Velocity Plane)

The inverse velocity plane of the composite substrate 3 may be identified using various methods. From another perspective, the inverse velocity 1/v (or velocity v from another perspective) in various directions (various ψ) may be identified using various methods. Hereafter, an example of a method for identifying the inverse velocity plane is described.

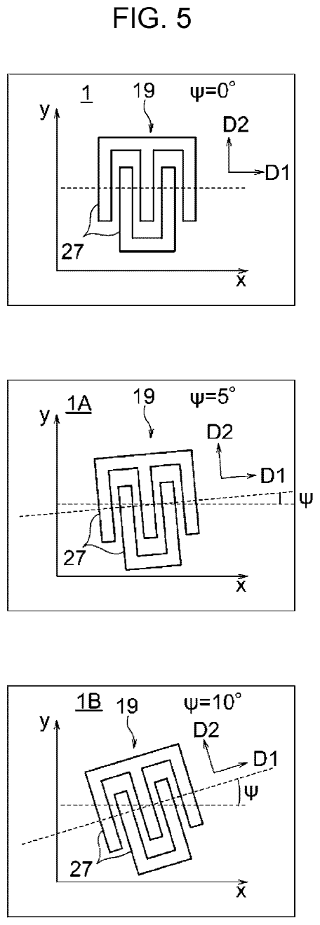

FIG. 5 is a schematic diagram for explaining a method for identifying the acoustic velocity v in various directions. As can be understood from the symbols in the figure, each of the three figures in FIG. 5 corresponds to a more schematic diagram of the plan view in FIG. 1.

The uppermost diagram in FIG. 5 schematically illustrates the acoustic wave element (resonator) for which the inverse velocity plane is to be identified. For convenience, symbols of the acoustic wave element 1 of the embodiment are used for this acoustic wave element. The middle drawing in FIG. 5 and the lowermost drawing in FIG. 5 schematically illustrate acoustic wave elements 1A and 1B used for convenience in identifying the inverse velocity plane of the acoustic wave element 1. The acoustic wave elements 1A and 1B have a configuration in which the IDT electrode 19 (and the reflectors 21 if needed) is rotated by ψ° around the z axis relative to the composite substrate 3 in the acoustic wave element 1. In the illustrated example, the acoustic wave elements 1A and 1B for which ψ=5° and ψ=10° are schematically illustrated. Except for w, the conditions of the acoustic wave elements 1, 1A, and 1B are identical to each other.

The acoustic wave element 1, for which the inverse velocity plane is to be identified, is, from another perspective, an acoustic wave element according to an embodiment (or example) or a comparative example, and, from yet another perspective, an acoustic wave element that is to be distributed or is actually distributed. The acoustic wave elements 1A and 1B used for convenience's sake are, from another perspective, manufactured for experiments to identify the inverse velocity plane of the acoustic wave element 1 or are assumed for simulation calculations to identify the inverse velocity plane.

In FIG. 1 to FIG. 3 and FIG. 5, a fixed Cartesian coordinate system D1D2D3 is affixed to the IDT electrode 19 for convenience. A D3 direction is a normal direction of the IDT electrode 19 (top surface of the composite substrate 3) and is identical to the z direction. A D1 direction is the arrangement direction of the multiple electrode fingers 27. A D2 direction is perpendicular to the D1 and D3 directions.

Returning to FIG. 5, the Cartesian coordinate system xyz is defined for the acoustic wave element 1 and is commonly used for the acoustic wave elements 1, 1A, and 1B, in each of which the orientation of the IDT electrode 19 is different. From another perspective, the Cartesian coordinate system xyx is fixed with respect to the composite substrate 3. On the other hand, the Cartesian coordinate system D1D2D3 is fixed with respect to the IDT electrode 19 and therefore different for each of the acoustic wave elements 1, 1A, and 1B.

As previously mentioned, among acoustic waves of various directions and various wavelengths excited by the IDT electrode 19, acoustic waves propagating in the arrangement direction (D1 direction) of the multiple electrode fingers 27, with the pitch p of the multiple electrode fingers 27 being approximately half the wavelength, are more likely to generate resonance. Therefore, the D1 direction can be regarded as the propagation direction of acoustic waves that generate resonance in the acoustic wave elements 1, 1A, and 1B.

The x direction is the propagation direction of acoustic waves that are intended to be utilized in the acoustic wave element 1. From another perspective, the x direction is the propagation direction of acoustic waves that generate resonance in the acoustic wave element 1. Therefore, in the acoustic wave element 1, the D1 direction coincides with the x direction. On the other hand, in the acoustic wave elements 1A and 1B, the D1 direction is inclined by w relative to the x direction.

The three previously described lines illustrated in FIG. 4 are examples of the characteristics of the acoustic wave elements 1, 1A, and 1B. The acoustic wave elements 1, 1A, and 1B have different resonance frequencies fr (and anti-resonance frequencies fa) from each other. Here, theoretically, the velocity v of the acoustic waves is the product of the resonance frequency fr and the wavelength λ (=2p). In the acoustic wave elements 1, 1A, and 1B, the pitches p of the electrode fingers are identical to each other. Therefore, the differences in resonance frequency fr are due to the fact that the velocities v of the acoustic waves propagating in the D1 direction differ from each other in the acoustic wave elements 1, 1A, and 1B.

From another perspective, the velocity v of acoustic waves in various directions (various ψ) can be obtained by finding the resonance frequency fr and calculating v=fr×2p for the multiple acoustic wave elements 1, 1A, and 1B, which each have a different D1 direction (in other words, ψ). Thus, the inverse velocity plane can be identified for the acoustic wave element 1. The identification of the velocity v of multiple acoustic wave elements with different D1 directions (in other words, the identification of the inverse velocity plane) may be performed by simulation calculation, by experiment, or by a combination of the two (e.g., correction or interpolation of the results of the other based on the results of one).

### (5.2. Example of Simulation Calculation)

The inventors of the present application performed simulation calculations under various conditions based on the above method for identifying the inverse velocity plane. As a result, the inventors could confirm that a concave inverse velocity plane is realized in the composite substrate 3 including the piezoelectric layer 11 and the low-acoustic-velocity film 9. Examples of simulations that were carried out are described below.

Conditions that are common to the various simulations described below (hereinafter referred to as “common conditions”) are as follows.
Composite substrate 3
   Piezoelectric layer 11
      Material: Rotated Y-cut X-propagation LT
   Low-acoustic-velocity film 9
      Material: SiO₂
   Support substrate 7
      Material: Si
      Thickness: Infinite
Conductor layer 5
   Two-layer structure consisting of Ti layer on piezoelectric layer 11 and Al—Cu layer on Ti layer
   Thickness of Ti layer: 60 Å (0.003λ)
   Thickness of Al—Cu alloy layer: 1400 Å (0.07λ)
   IDT electrode 19
      Pitch p: 1 μm
      Duty: 0.5
      Number of fingers: Infinite

In the above, Duty is the width of the electrode fingers 27 (length in the D1 direction) divided by the pitch p. In the simulation calculations, the impedance at each frequency was calculated using an FEM (finite element method), as illustrated in FIG. 4. From the calculation results, the resonance frequency fr was identified and the inverse velocity 1/v was calculated.

FIGS. 6 to 8 each illustrate an example of simulation results. The horizontal and vertical axes of these figures are as described in the previous discussion relating to FIG. 6.

FIG. 6 illustrates inverse velocity planes for three cases in which the normalized thicknesses a of the piezoelectric layer 11 are different from each other, as indicated in the legend in figure. With respect to the simulation results illustrated in FIG. 6, simulation conditions other than the common conditions described previously are as follows.
Normalized thickness a of piezoelectric layer 11: 0.20, 0.30, or 0.40
Normalized thickness b of low-acoustic-velocity film 9: 0.01
Cut angle c of piezoelectric layer 11: 26°

The fact that a concave inverse velocity plane can be realized by the composite substrate 3 including the piezoelectric layer 11 and the low-acoustic-velocity film 9 could be confirmed from the cases with the normalized thicknesses a of 0.30 and 0.40 (lines L2 and L3).

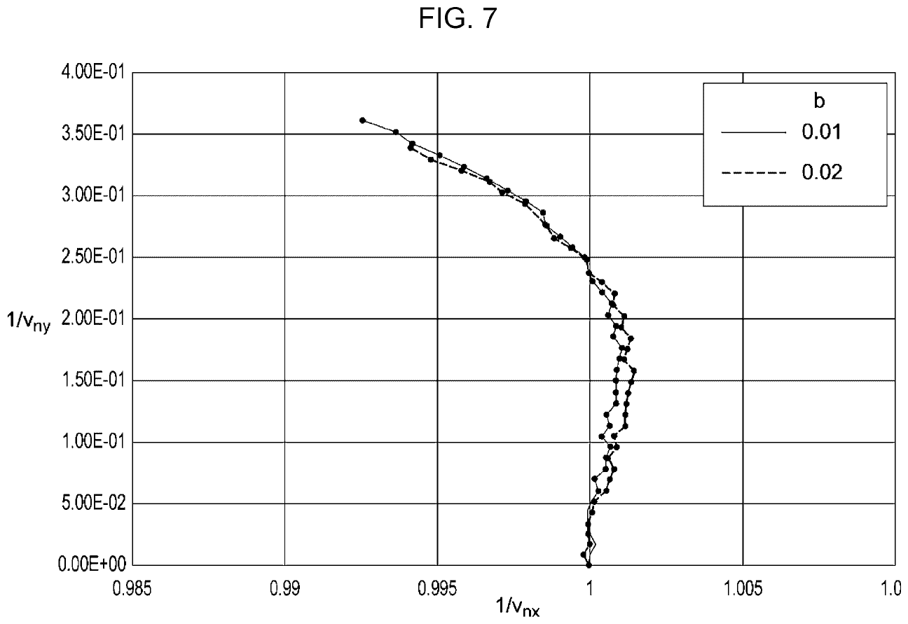

FIG. 7 illustrates examples of inverse velocity planes of two cases in which the normalized thicknesses b of the low-acoustic-velocity film 9 are different from each other, as indicated in the legend in the figure. With respect to the simulation results illustrated in FIG. 7, simulation conditions other than the common conditions described previously are as follows.
Normalized thickness a of piezoelectric layer 11: 0.30
Normalized thickness b of low-acoustic-velocity film 9: 0.01 or 0.02
Cut angle c of piezoelectric layer 11: 26°

Note that the case of b=0.01 in FIG. 7 is the same as the case of a=0.30 in FIG. 6, as can be understood from comparison with the previous paragraph. From FIG. 7, the inventors could confirm that a concave inverse velocity plane can be realized by the composite substrate 3 including the piezoelectric layer 11 and the low-acoustic-velocity film 9.

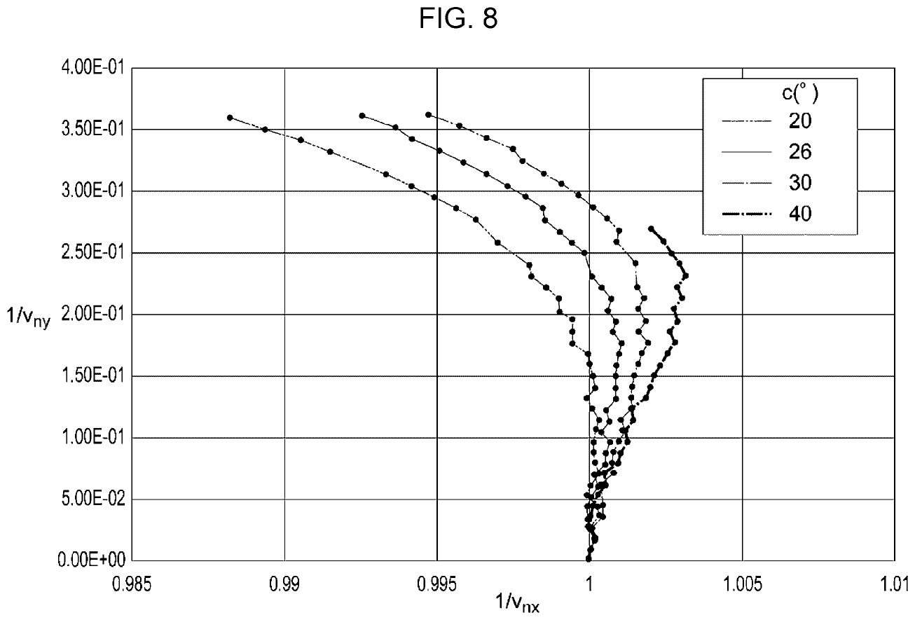

FIG. 8 illustrates inverse velocity planes for four cases in which the cut angles c (°) of the piezoelectric layer 11 are different from each other, as indicated in the legend in figure. With respect to the simulation results illustrated in FIG. 8, simulation conditions other than the common conditions described previously are as follows.
Normalized thickness a of piezoelectric layer 11: 0.30
Normalized thickness b of low-acoustic-velocity film 9: 0.01
Cut angle c of piezoelectric layer 11: 20°, 26°, 30°, or 40°

Note that the case of c=26° in FIG. 8 is the same as the case of a=0.30 in FIG. 6, as can be understood from comparison with the previous paragraph. From FIG. 8, the inventors could confirm that a concave inverse velocity plane can be realized by the composite substrate 3 including the piezoelectric layer 11 and the low-acoustic-velocity film 9.

(5.3. Equation Representing Conditions Under which Inverse Velocity Plane is Realized)

The inventors of the present application obtained the previously mentioned Equation (1) by performing a large number of simulation calculations whiles setting various values for the normalized thicknesses a and b and the cut angle c. The process used to obtain Equation (1) is described below. The effects of conditions other than a, b, and c (for example, the thickness of the electrode fingers 27 and the thickness of the support substrate 7) on whether the inverse velocity plane is concave or convex are relatively small, unless these conditions are unique conditions.

An inverse velocity plane can be approximated by a parabola (quadratic curve), which is not illustrated. This parabola is represented by a function 1/v(ψ) having ψ as a variable. Then, v(ψ) can be expressed by the following equation in a range where ψ is relatively small.

$$v ( ψ ) = {v}_{0} \times ( 1 + γ / 2 \times {ψ}^{2} ) \qquad ( 3 )$$

A velocity v₀ is the velocity v of the acoustic waves for ψ=0°. Therefore, Equation (3) can be rewritten as the following equation for the normalized velocity 1/vₙ.

$$1 / {v}_{n} ( ψ ) = 1 / ( 1 + γ / 2 \times {ψ}^{2} ) \qquad ( 4 )$$

Although not particularly illustrated, when γ<−1, the line (inverse velocity plane) represented by Equation (4) is a concave curve that passes through the point where 1/vₓ=1 and 1/v_{y}=0 (referred to as a first point in this paragraph). When γ=−1, the line represented by Equation (4) is a straight line that passes through the first point and is parallel to the vertical axis 1/v_{y}. When γ>−1, the line represented by Equation (4) is a convex curve that passes through the first point.

As the values of a, b and c change, the shape of the inverse velocity plane changes. From another perspective, γ correlates with a, b, and c when the inverse velocity plane is approximated by a parabola. Therefore, the inverse velocity plane can be said to be concave when the value of γ is obtained from the values of a, b, and c, and the obtained value of γ is less than −1. From another perspective, a, b, and c may be set so that the value of γ identified based on the values of a, b, and c is less than −1 so as to achieve a concave inverse velocity plane.

Various methods may be used to identify the value of γ based on the values of a, b and c. For example, an equation may be used to calculate the value of γ based on the values of a, b, and c, as described below. In the previously mentioned Equation (1), the left side corresponds to an equation for calculating the value of γ from the values of a, b, and c. A map that maps the values of a, b, and c, and the values of γ to each other may be referenced to identify the values of γ corresponding to the values of a, b and c. In addition, AI (artificial intelligence) technology may be used to identify the values of γ corresponding to the values of a, b and c. In these various identification methods, other conditions besides a, b, and c may be incorporated as factors that specify the value of γ.

As touched on above, the left side of Equation (1) corresponds to an equation for calculating the value of γ from the values of a, b, and c. This equation was obtained via the following procedure. First, the inverse velocity plane was identified by performing simulation calculations (previously described) for obtaining the inverse velocity plane for each of multiple cases in which the values of a, b, and c were changed to various values. For each inverse velocity plane, the best approximation among parabolas expressed by Equation (4) was obtained using the least-squares method. That is, the value of γ was obtained for each combination of the values of a, b, and c. This identification of the closest parabola was performed for inverse velocity planes for which ψ is greater than or equal to 0° and less than or equal to 15°. Then, based on the various values of a, b, and c used in the simulation and the corresponding various values of γ, nonlinear multiple regression analysis using the least squares method was performed to obtain an equation for calculating γ from a, b, and c.

In a simulation to obtain the left-hand side of Equation (1), the conditions other than the common conditions already described are as follows.
Normalized thickness a: Varied in range greater than or equal to 0.1 and less than or equal to 0.6 in increments of 0.1.
Normalized thickness b: Varied in range greater than or equal to 0.1 and less than or equal to 0.6 in increments of 0.1.
Cut angle c: Varied in range greater than or equal to 10° and less than or equal to 80° in increments of 10°

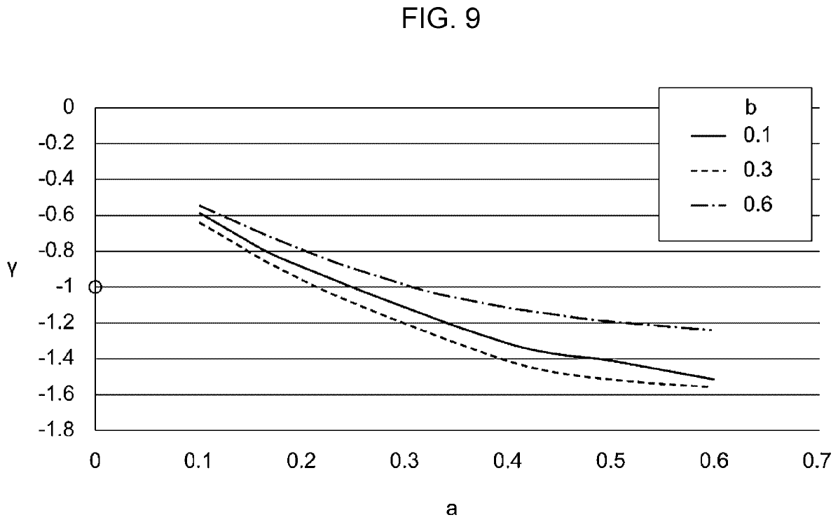

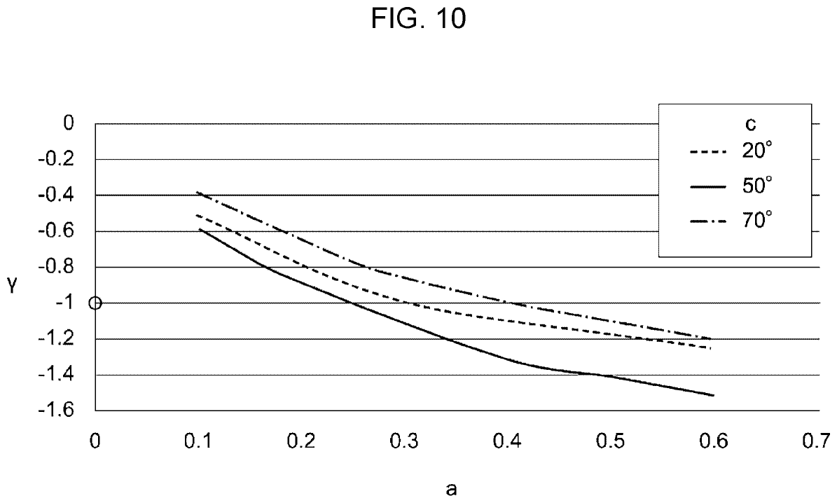

FIGS. 9 and 10 illustrate the values of γ calculated by the left side of Equation (1). In these figures, the horizontal axis represents the normalized thickness a. The vertical axis represents γ.

In FIG. 9, three lines are illustrated for which the normalized thicknesses b of the low-acoustic-velocity film 9 are different from each other, as indicated in the legend in the figure. Specifically, b for the three lines is 0.1, 0.3, or 0.6. The cut angle c for the three lines is 50°.

In FIG. 10, three lines are illustrated for which the cut angles c of the piezoelectric layer 11 are different from each other as indicated by the legend in the figure. Specifically, c for the three lines is 20°, 50°, or 70°. The normalized thickness b for the three lines is 0.1.

(5.4. Examination of Conditions Under which Inverse Velocity Plane is Realized)

Tendencies of the conditions under which concave inverse velocity planes are realized can be discerned from FIGS. 6 to 10.

For example, as illustrated in FIGS. 9 and 10, the larger the value of the normalized thickness a of the piezoelectric layer 11, the smaller the value of γ. In other words, the larger the value of normalized thickness a, the more easily a concave inverse velocity plane is realized. This is also consistent with the fact that the inverse velocity plane transitions from being convex to concave as the normalized thickness a increases in FIG. 6.

As illustrated in FIG. 9, for example, the closer the value of the normalized thickness b of the low-acoustic-velocity film 9 is to a value between the lower limit (0.1) and the upper limit (0.6) of the condition of the current simulation (the value illustrated in FIG. 9 is 0.3), the smaller the value of γ is. In other words, the closer the value of the normalized thickness b is to a specific value (not necessarily 0.3), the more easily a concave inverse velocity plane is realized.

As illustrated in FIG. 10, for example, the closer the value of the cut angle c is to a value between a value close to the lower limit (20°) and a value close to the upper limit (70°) of the condition of the current simulation (the value illustrated in FIG. 10 is 50°), the smaller the value of γ is. In other words, the closer the value of the cut angle c is to a specific value (not necessarily 50°), the more easily a concave inverse velocity plane is realized.

In FIGS. 6 to 10, a case in which the material of the piezoelectric layer 11 and the material of the low-acoustic-velocity film 9 are specific materials (rotated Y-cut X-propagation LT and SiO₂) is taken as an example. However, taking into account the tendencies described above and technical common sense, we can see that concave inverse velocity planes can be realized even with other materials. For example, this is described below.

As described with reference to FIGS. 6 and 9, as the normalized thickness a of the piezoelectric layer 11 becomes relatively larger, γ tends to be less than −1. A reason why this tendency appears is, for example, that among the effects of the piezoelectric layer 11 and the low-acoustic-velocity film 9 on the inverse velocity plane, the effect of the piezoelectric layer 11 on the inverse velocity plane is larger, and the shape of the inverse velocity plane is more likely to appear in just the material of the piezoelectric layer 11.

On the other hand, for example, when the piezoelectric layer 11 is composed of LT that is not rotated Y-cut X-propagation or LN of any cut angle, the acoustic velocities in directions with different angles (see w) around the normal of the piezoelectric layer 11 are different from each other. Therefore, if a direction with a higher acoustic velocity, among the above different directions, is set as the x direction (propagation direction of acoustic waves intended to be used) and the normalized thickness a of the piezoelectric layer 11 is relatively large, a concave inverse velocity plane is realized.

As mentioned with reference to FIG. 10, with respect to the normalized thickness b of the low-acoustic-velocity film 9, there is a size at which γ is likely to be small. Therefore, a concave inverse velocity plane can also be realized while reducing the normalized thickness a of the piezoelectric layer 11 by searching for a normalized thickness b of a size at which γ is likely to be small. We believe that this tendency will not change even if the material of the low-acoustic-velocity film 9 is a material other than SiO₂.

### 6. Summary of First Embodiment

As described above, the composite substrate 3 according to this embodiment includes the piezoelectric layer 11 and the low-acoustic-velocity film 9 that extends along the bottom surface of the piezoelectric layer 11 and has a lower acoustic velocity than the piezoelectric layer 11. An inverse velocity plane of the acoustic waves propagating through the piezoelectric layer 11 is concave.

From another perspective, the acoustic wave element 1 according to this embodiment includes the composite substrate 3 as described above and a first IDT electrode (IDT electrode 19). The IDT electrode 19 includes multiple electrode fingers 27 that are arranged along the top surface of the piezoelectric layer 11.

Thus, for example, the effect of the inverse velocity plane being concave can be obtained while still obtaining the effects of the composite substrate 3. The effects of the composite substrate 3 include, for example, the effect of the energy of the acoustic waves being confined and the effect of higher frequencies being available by utilizing plate waves. One effect of the inverse velocity plane being concave is that, for example, transverse mode spurious between the resonance frequency fr and the anti-resonance frequency fa is more easily reduced than in the case where the inverse velocity plane is convex. Here, as previously mentioned, the inventors of the present application were first to discover that a concave inverse velocity plane can be realized in the composite substrate 3.

The piezoelectric layer 11 and low-acoustic-velocity film 9 may be directly stacked on each other from an acoustic point of view. The piezoelectric layer 11 may be composed of rotated Y-cut X-propagation lithium tantalate single crystal. The low-acoustic-velocity film may be composed of SiO₂. Here, λ (μm) is twice the pitch p of the multiple electrode fingers 27. The normalized thickness of the piezoelectric layer 11, which is obtained by dividing the thickness a′ (μm) of the piezoelectric layer 11 by λ, is denoted by a. The normalized thickness of the low-acoustic-velocity film 9, which is obtained by dividing the thickness b′ of the low-acoustic-velocity film 9, by λ, is denoted by b. The tilt angle of the Y axis with respect to the normal (z axis) of the piezoelectric layer 11 is c (°). In this case, a, b, and c may have values that satisfy the previously described Equation (1).

In this case, for example, a, b, and c have values that lie within ranges where simulation calculations have confirmed that a concave inverse velocity plane is realized. Thus, a concave inverse velocity plane is stably realized.

The normalized thickness a of the piezoelectric layer 11 may be less than or equal to 1.0. In this case, for example, since the normalized thickness a is sufficiently small, the effects of the composite substrate 3 are readily achieved.

The normalized thickness b of the low-acoustic-velocity film may be less than or equal to 0.5. Here, as illustrated in FIG. 9, γ is more likely to be less than −1 when the normalized thickness b is 0.1 or 0.3, compared to when the normalized thickness b is 0.6. Thus, a normalized thickness b of 0.5 or less facilitates, for example, the realization of a concave inverse velocity plane.

### Second Embodiment

FIG. 11 is a sectional view illustrating the configuration of an acoustic wave element 201 according to a Second Embodiment. This figure corresponds to FIG. 2 of the First Embodiment.

A composite substrate 203 of the acoustic wave element 201 includes a high-acoustic-velocity film 13 between the piezoelectric layer 11 and the low-acoustic-velocity film 9. The acoustic velocity in the high-acoustic-velocity film 13 is higher than the acoustic velocity in the piezoelectric layer 11. The high-acoustic-velocity film 13 is directly stacked on the piezoelectric layer 11 and the low-acoustic-velocity film 9 from an acoustic point of view. In the Second Embodiment as well, similarly to as in the First Embodiment, a concave inverse velocity plane is realized. The conditions used when comparing acoustic velocities (e.g., comparing phase velocities of bulk waves) and the meaning of directly stacked from an acoustic point of view are the same as described in the descriptions of the piezoelectric layer 11 and the low-acoustic-velocity film 9 in the First Embodiment.

The material of the high-acoustic-velocity film 13 may be any material so long as the acoustic velocity in the high-acoustic-velocity film 13 is higher than the acoustic velocity in the piezoelectric layer 11. Physical properties (density, Young's modulus, acoustic impedance, etc.) that have an effect on acoustic velocity may also be set to any values. Examples of the specific material of the high-acoustic-velocity film 13 include aluminum oxide (Al₂O₃), silicon nitride (Si₃N₄), and aluminum nitride (AlN). When the material of the high-acoustic-velocity film 13 is a material mentioned in this paragraph, some or all of the conditions for comparison of acoustic velocities described in the description of the First Embodiment may be ignored.

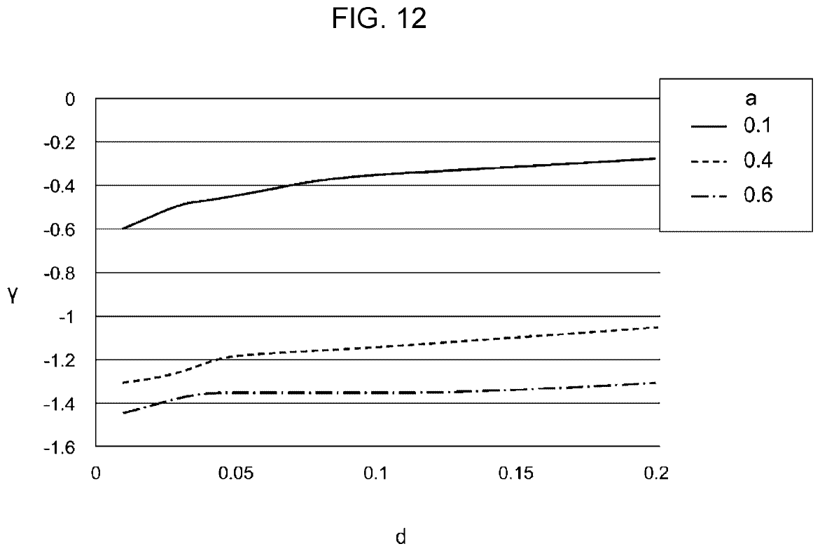

A normalized thickness d of the high-acoustic-velocity film 13 is a value obtained by dividing a thickness d′ (μm) of the high-acoustic-velocity film 13 by the wavelength λ (μm). The normalized thickness d of the low-acoustic-velocity film 9 may have a value that satisfies Equation (2) described below. When Equation (2) is satisfied or not satisfied, the lower limit and upper limit of the normalized thickness d when realizing a concave inverse velocity plane may be set as appropriate. For example, the normalized thickness d may be greater than or equal to 0.01 and less than or equal to 0.2. The inventors of the present application confirmed that a concave inverse velocity plane is realized at such thicknesses as indicated by the values of γ based on the simulation results described below (FIG. 12).

The material and thickness of the high-acoustic-velocity film 13 affect the realization of a concave inverse velocity plane. In this embodiment, an example in which the material of high-acoustic-velocity film 13 is Al₂O₃ is described, and the specific value of the thickness that allows a concave inverse velocity plane to be realized is described. However, as described below, even when the material of the high-acoustic-velocity film is a material other than Al₂O₃, a concave inverse velocity plane can be achieved by setting the thickness of the high-acoustic-velocity film 13 and the conditions of the other layers as appropriate.

In the acoustic wave element 201, the normalized thickness a of the piezoelectric layer 11, the normalized thickness b of the low-acoustic-velocity film 9, the cut angle) c (° of the piezoelectric layer 11 (rotated Y-cut X-propagation LT), and the normalized thickness d of the high-acoustic-velocity film 13 may be set so that the following Equation (2) is satisfied.

$$- 3.26163 a - 0.30469 b - 0.02132 c + 3.843127 d + 2.196667 {a}^{2} + 0.960417 {b}^{2} + 0.00026 {c}^{2} - 7.75985 {d}^{2} - 0.01579 ab + 0.001339 ac - 1.26908 ad - 0.00246 b c - 0.8485 b d - 0.01067 c d + 0.15 \; 1192 < - 1 \qquad ( 2 )$$

The method for obtaining the above Equation (2) is the same as or similar to the method for obtaining Equation (1) in the First Embodiment. In the simulation of the Second Embodiment, conditions that differ from those used in the First Embodiment are as follows.
High-acoustic-velocity film 13
   Material: Al₂O₃
   Normalized thickness: 0.01, 0.03, 0.05, 0.1, or 0.2

FIG. 12 illustrate the values of γ calculated by the left side of Equation (2). In these figures, the horizontal axis represents the normalized thickness d. The vertical axis represents γ. In FIG. 12, three lines are illustrated for which the normalized thicknesses a of the piezoelectric layer 11 are different from each other as indicated in the legend in the figure. Specifically, a for the three lines is 0.1, 0.4, or 0.6. For the three lines, the normalized thickness b of the low-acoustic-velocity film 9 is 0.2, and the cut angle c is 40°.

As illustrated in FIG. 12, the smaller the value of the normalized thickness d of the high-acoustic-velocity film 13, the smaller the value of γ. Similarly to as in Embodiment 1, the larger the normalized thickness a of the piezoelectric layer 11, the smaller the value of γ. The tendencies illustrated in FIG. 12 indicate that a concave inverse velocity plane can be achieved by increasing the normalized thickness a and decreasing the normalized thickness d, even for materials other than those used in the simulation.

As described above, in the Second Embodiment as well, the composite substrate 203 includes the piezoelectric layer 11 and the low-acoustic-velocity film 9 that extends along the bottom surface of the piezoelectric layer 11 and has a lower acoustic velocity than the piezoelectric layer 11. An inverse velocity plane of the acoustic waves propagating through the piezoelectric layer 11 is concave. Therefore, substantially the same effects as in the First Embodiment are achieved.

The composite substrate 203 may further include the high-acoustic-velocity film 13 between the piezoelectric layer 11 and the low-acoustic-velocity film 9. The high-acoustic-velocity film 13 is directly stacked on the piezoelectric layer 11 and the low-acoustic-velocity film 9 from an acoustic point of view. The piezoelectric layer 11 may be composed of rotated Y-cut X-propagation lithium tantalate single crystal. The low-acoustic-velocity film 9 may be composed of silicon dioxide. The high-acoustic-velocity film 13 may be composed of aluminum oxide. Here, λ (μm) is twice the pitch p of the multiple electrode fingers 27. The normalized thickness of the piezoelectric layer 11, which is obtained by dividing the thickness a′ (μm) of the piezoelectric layer 11 by λ, is denoted by a. The normalized thickness of the low-acoustic-velocity film 9, which is obtained by dividing the thickness b′ of the low-acoustic-velocity film 9, by λ, is denoted by b. The tilt angle of the Y axis with respect to the normal of the piezoelectric layer 11 is c (°). A normalized thickness of the high-acoustic-velocity film 13, which is obtained by dividing the thickness d′ of the high-acoustic-velocity film 13 by λ, is denoted by d. In this case, a, b, c, and d may have values that satisfy the previously mentioned Equation (2).

In this case, the same or similar effects are achieved as when Equation (1) is satisfied in the First Embodiment. For example, a, b, c, and d have values that lie within ranges where simulation calculations have confirmed that a concave inverse velocity plane is realized. Thus, a concave inverse velocity plane is stably realized.

### Other Embodiments

Although not particularly illustrated, the composite substrate may have a configuration other than those in the First and Second Embodiments.

For example, the composite substrate may include, in order from the top, the piezoelectric layer 11, the low-acoustic-velocity film 9, the high-acoustic-velocity film 13, and the support substrate 7. In other words, in the Second Embodiment, the position relationship of the low-acoustic-velocity film 9 and the high-acoustic-velocity film 13 may be reversed. The inventors of the present application confirmed through simulation calculations that the high-acoustic-velocity film 13 in this case has little effect on whether the inverse velocity plane is concave or convex. Thus, for example, when realizing a concave inverse velocity plane, the values of a, b, and c may be set so that Equation (1) of the First Embodiment is satisfied.

For example, the composite substrate may include a multilayer film composed of a total of three or more layers of the low-acoustic-velocity film 9 and high-acoustic-velocity film 13 between the piezoelectric layer 11 and the support substrate 7. In the multilayer film, the low-acoustic-velocity film 9 and the high-acoustic-velocity film 13 are stacked in an alternating manner. When the uppermost layer of the multilayer film (the layer in contact with the piezoelectric layer 11) is the low-acoustic-velocity film 9, for example, a concave inverse velocity plane may be realized by satisfying Equation (1). When the uppermost layer of the multilayer film is the high-acoustic-velocity film 13, for example, a concave inverse velocity plane may be realized by satisfying Equation (2).

### <Variations>

Hereafter, variations of the IDT electrode will be described. In the description of the variations, the symbols of the First Embodiment may be used for convenience. However, the variations may be applied to embodiments other than the First Embodiment.

### (First Variation)

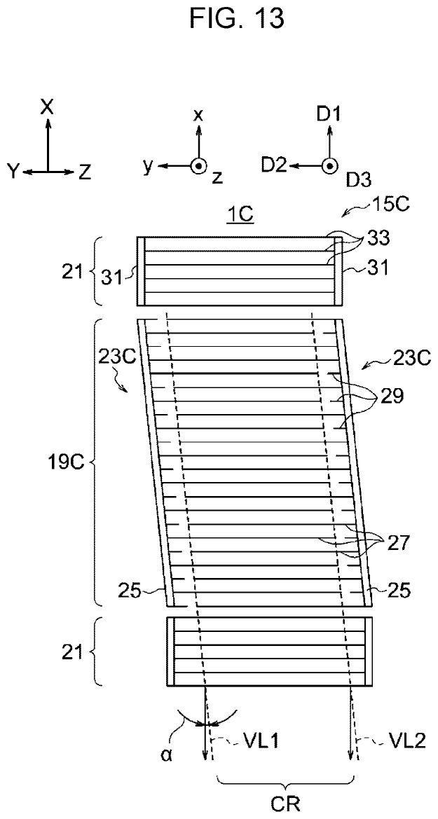

FIG. 13 is a plan view illustrating the configuration of an acoustic wave element 1C (resonator 15C) according to a First Variation. This figure corresponds to FIG. 1.

In short, the acoustic wave element 1C has a configuration in which an IDT electrode 19C is tilted at an angle with respect to the x direction (the propagation direction of acoustic waves that are intended to be used). This enables transverse mode spurious to be further reduced. This is described more specifically below.

A line VL1 is a virtual line connecting tips of multiple electrode fingers 27 of one comb electrode 23C. A line VL2 is a virtual line connecting tips of multiple electrode fingers 27 of another comb electrode 23C. In this case, the lines VL1 and VL2 are inclined with respect to the x direction. The x direction is, for example, the direction in which the multiple electrode fingers 27 are arranged and is perpendicular to the direction in which the multiple electrode fingers 27 extend. A region sandwiched between the lines VL1 and VL2 is a crossing region CR where multiple electrode fingers 27 of the pair of comb electrodes 23C cross each other.

An angle α is the inclination angle of the lines VL1 and VL2 with respect to the x direction. The angle α may be the same for the lines VL1 and VL2 (illustrated example) or may be different for the lines VL1 and VL2. The specific value of the angle α may be any value, for example, may be greater than or equal to 0°, 5°, 10°, or 15°, and may be less than or equal to 45°, 30°, 15°, or 10°. The lower and upper limits above may be combined with each other in any manner so long as no inconsistencies arise. The line VL1 and/or the line VL2 may be a single straight line along their entire length, or may include bends (angular or curved).

In the illustrated example, the reflectors 21 have a configuration the same as or similar to that of the reflectors 21 of the embodiment. However, the reflectors 21 may be inclined with respect to the x direction, the same as or similar to the IDT electrode 19C. Specifically, for example, the busbars 31 of the reflectors 21 may extend parallel to the virtual lines VL1 and VL2.

As described above, the first IDT electrode (IDT electrode 19C) includes a first busbar (busbar 25 of one comb electrode 23C) and a second busbar (busbar 25 of the other comb electrode 23C), multiple first electrode fingers (multiple electrode fingers 27 of one comb electrode 23C), and multiple second electrode fingers (multiple electrode fingers 27 of the other comb electrode 23C). The two busbars 25 face each other in a direction that intersects the x direction (propagation direction of acoustic waves) when the piezoelectric layer 11 is viewed in plan view. The multiple first electrode fingers extend in the y direction perpendicular to the x direction from the first busbar toward the second busbar. The multiple second electrode fingers extend in the y direction from the second busbar toward the first busbar and are arranged in an alternating manner with the multiple first electrode fingers in the x direction. The virtual line VL1 connecting the tips of the multiple first electrode fingers and the virtual line VL2 connecting the tips of the multiple second electrode fingers are inclined with respect to the x direction.

In this case, for example, transverse mode spurious can be reduced due to the inverse velocity plane being concave and transverse mode spurious can also be reduced due to the crossing region CR being inclined.

### (Second Variation)

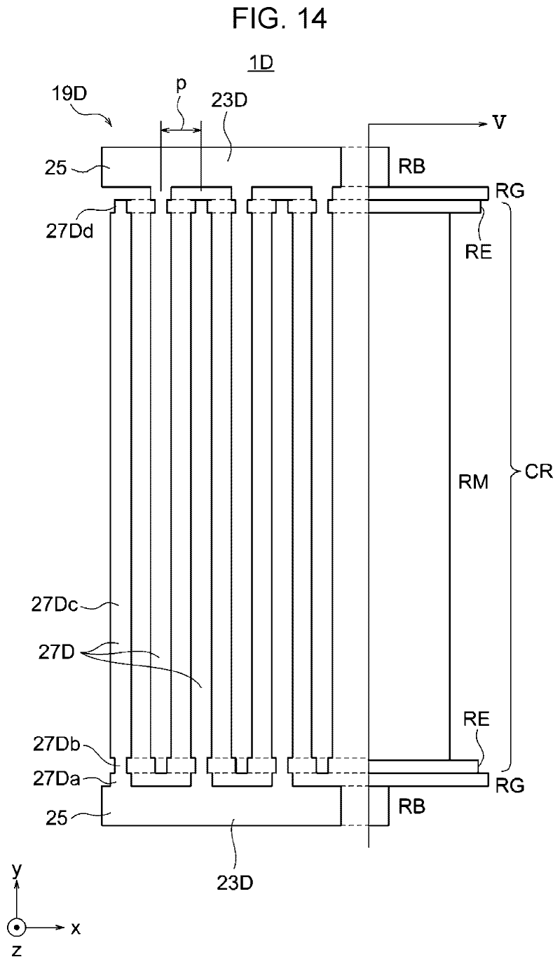

FIG. 14 is a schematic diagram for describing an acoustic wave element 1D according to a Second Variation. In the description of this variation, unlike the description of the other embodiments, the acoustic velocity is assumed to be an acoustic velocity for which the effect of the conductor layer 5 (symbol omitted in FIG. 14) is taken into account, unless otherwise noted.

The left-hand part of FIG. 14 is a plan view illustrating the configuration of part of the acoustic wave element 1D and corresponds to part of FIG. 1. The right-hand part of FIG. 14 is a graph illustrating the acoustic velocity profile in the acoustic wave element 1D.

An axis parallel to the y direction in the graph on the right-hand side of FIG. 14 represents positions in an IDT electrode 19D in the y direction, and corresponding positions are connected by dotted lines. An axis parallel to the x direction represents acoustic velocity V. Along this axis, the right-hand side of FIG. 14 (the +x side) corresponds to the side with the higher acoustic velocity.

The graph on the right-hand side of FIG. 1 merely illustrates the ranking of acoustic velocities in multiple regions. In other words, the actual values are not necessarily reflected in the absolute values of the acoustic velocity in each region, the differences in acoustic velocity between multiple regions, and the acoustic velocity ratio between multiple regions.

The symbols (CR, RM, RE, RG, and RB) on the right-hand side of FIG. 14 are the symbols affixed to different regions within the IDT electrode 19D. Specifically, in the illustrated example, the IDT electrode 19 includes the crossing region CR mentioned in the description of the First Variation, busbar regions RB where the busbars 25 are positioned, and gap regions RG located between the crossing region CR and the busbar regions RB.

In short, in the acoustic wave element 1D, the IDT electrode 19D is shaped so as to utilize a piston mode. A piston mode, for example, can be said to be a mode in which the amplitude is substantially constant in at least a central region of the crossing region CR when looking at a yz cross section, and the amplitude sharply falls outside that region.

In order to utilize the piston mode, for example, the IDT electrode 19D includes three or more regions in the crossing region CR where the acoustic velocities of the acoustic waves differ from each other. In the illustrated example, the crossing region CR includes a central region RM located in the center of the crossing region CR and two edge regions RE located at both edges of the crossing region CR. The shape of the IDT electrode 19D is designed so that the acoustic velocity in the central region RM is different from that in the edge regions RE.

More precisely, in the illustrated example, each electrode finger 27 includes, in order from a base side to a tip side, a first part 27Da located in the first gap region RG, a second part 27Db located in the first edge region RE, a third part 27Dc located in the central region RM, and a fourth part 27Dd located in the second edge region RE. The width of the second region 27Db and the fourth region 27Dd, which are positioned in the edge regions RE, is different from the width of the other regions. As a result, the acoustic velocity in the central region RM is different from the acoustic velocity in the edge regions RE.

The acoustic velocity, taking into account the effect of the IDT electrode 19D, depends on the thickness of the conductor layer 5 and so on, and is lower in regions where a larger proportion of the area is constituted by the conductor layer 5. Therefore, in the illustrated example, the regions in order from the one with the lowest acoustic velocity are the busbar region RB, the central region RM, and the gap region RG. The acoustic velocity of the edge regions RE may be higher (illustrated example) or lower than that of the central region RM. In the illustrated example, the width of the second part 27Db and the fourth part 27Dd is smaller than that of third part 27Dc, and therefore the acoustic velocity in the edge region RE is higher than that of the central region RM.

The proportion occupied by the central region RM in the width direction (y direction) of the crossing region CR may be freely set. Typically, the central region RM is set to be relatively wide. For example, the central region RM is at least ½ or ⅔ the width of the crossing region CR. The crossing region CR and the two edge regions RE are positioned with line symmetry with respect to a center line of the crossing region CR, for example.

Various types of acoustic wave elements using piston modes are possible in addition to the illustrated example. For example, the central region RM and/or the edge regions RE may be further divided into regions having different acoustic velocities from each other. For example, from another perspective, the crossing region CR may include an odd number of five or more regions having different acoustic velocities that are lineally symmetrical about the center line of the crossing region CR. In the illustrated example, the IDT electrode 19D does not include the dummy electrodes 29, but may include the dummy electrodes 29. Specific regions for utilizing the piston mode (the edge regions RE in the illustrated example) may be formed in the gap regions RG and/or busbar regions RB, in addition to or instead of the crossing region CR. For example, differences in acoustic velocity may be realized by differences in the thickness of the conductor layer 5, or by differences in the presence and/or thickness of other layers overlapping the conductor layer 5. In an acoustic wave element utilizing a piston mode, the crossing region CR may be inclined with respect to the x direction, as illustrated in the First Variation.

As described above, the first IDT electrode (IDT electrode 19D) includes a first busbar (busbar 25 of one comb electrode 23D) and a second busbar (busbar 25 of the other comb electrode 23D), multiple first electrode fingers (multiple electrode fingers 27D of one comb electrode 23D), and multiple second electrode fingers (multiple electrode fingers 27D of the other comb electrode 23D). The two busbars 25 face each other in a direction that intersects the x direction (propagation direction of acoustic waves) when the piezoelectric layer 11 is viewed in plan view. The multiple first electrode fingers extend in the y direction perpendicular to the x direction from the first busbar toward the second busbar. The multiple second electrode fingers extend in the y direction from the second busbar toward the first busbar and are arranged in an alternating manner with the multiple first electrode fingers in the x direction. The crossing region CR is sandwiched between the virtual line VL1 (see FIG. 13 for the symbol) connecting the tips of the multiple first electrode fingers and the virtual line VL2 (see FIG. 13 for the symbol) connecting the tips of the multiple second electrode fingers. The crossing region CR includes the two edge regions RE and the central region RM. The two edge regions RE may be adjacent to the two virtual lines VL1 and VL2. The central region RM may be positioned more centrally in the crossing region CR than the two edge regions RE. The velocity of the acoustic waves excited by the IDT electrode 19D and propagating through the piezoelectric layer 11 may be different in the central region RM and the two edge regions RE.

In this case, for example, transverse mode spurious can be reduced due to the inverse velocity plane being concave, and transverse mode spurious can be reduced due to a piston mode being used.

### (Filter and Splitter)

In the description up to this point, the acoustic wave element 1 has been described as being the resonator 15. However, the acoustic wave element 1 may be a filter or splitter, as described below. In the description given here, the symbols of the First Embodiment are used for convenience, but the acoustic wave element according to the Second Embodiment or variations may be a filter or a splitter.

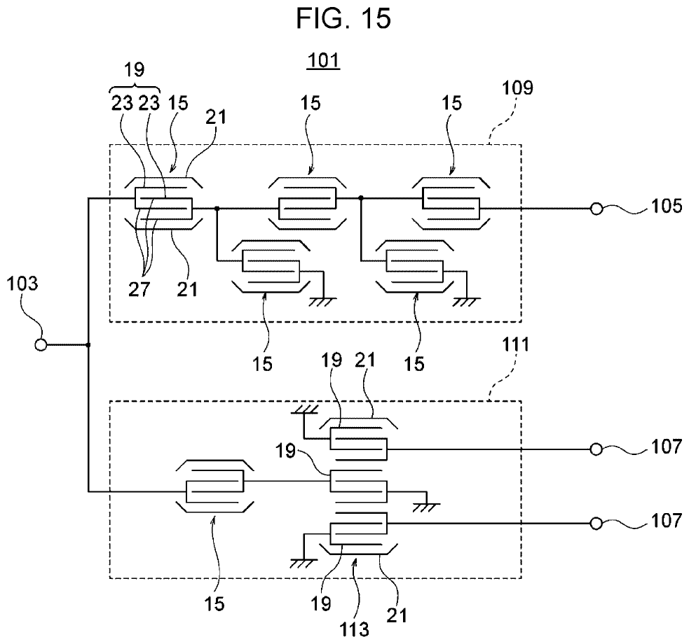

FIG. 15 is a circuit diagram schematically illustrating the configuration of a splitter 101. The splitter 101 may be an example of an acoustic wave element. In this figure, the comb electrodes 23 are each schematically illustrated in the shape of a two-pronged fork, and the reflectors 21 are each represented by a single line bent at both ends, as indicated by the symbols in the upper left corner of the figure.

The splitter 101 includes, for example, a transmission filter 109 that filters a transmission signal from a transmission terminal 105 and outputs the filtered transmission signal to an antenna terminal 103, and a reception filter 111 that filters a reception signal from the antenna terminal 103 and outputs the filtered reception signal to a pair of reception terminals 107. The transmission filter 109 and the reception filter 111 may each be an example of an acoustic wave element.

The transmission filter 109 is, for example, configured as a ladder filter consisting of multiple resonators 15 connected in a ladder configuration. In other words, the transmission filter 109 includes multiple (or even just one) resonators 15 (series resonators) connected in series between the transmission terminal 105 and the antenna terminal 103, and multiple (or even just one) resonators 15 (parallel arms, parallel resonators) connected between the series line (series arm) and a reference potential. The multiple resonators 15 constituting the transmission filter 109 are provided on the same composite substrate 3, for example.

The reception filter 111 includes, for example, a resonator 15 and a multi-mode filter (which is assumed to include a dual-mode filter) 113. The multi-mode filter 113 may be an example of an acoustic wave element. The multi-mode filter 113 includes multiple (three in the illustrated example) IDT electrodes 19 (from another perspective, resonators 16. Here the symbols are omitted) arranged in the propagation direction of acoustic waves and a pair of reflectors 21 disposed on both sides of the IDT electrodes. The resonator 15 and the multi-mode filter 113 constituting the reception filter 111 are provided on the same composite substrate 3, for example.

The transmission filter 109 and the reception filter 111 may be provided on the same composite substrate 3 or on different composite substrates 3 from each other. FIG. 15 merely illustrates an example configuration of the splitter 101, and for example, the reception filter 111 may be configured as a ladder filter similarly to the transmission filter 109. The series resonators and parallel resonators that make up a single ladder filter may be provided on separate composite substrates 3. The splitter 101 (multiplexer) is not limited to a duplexer including the transmission filter 109 and the reception filter 111. For example, the splitter may be a diplexer or may contain three or more filters (for example, a triplexer or quadplexer).

### (Module and Communication Device)

The acoustic wave elements may be used, for example, in a module and/or communication device for communication. One example is illustrated hereafter.

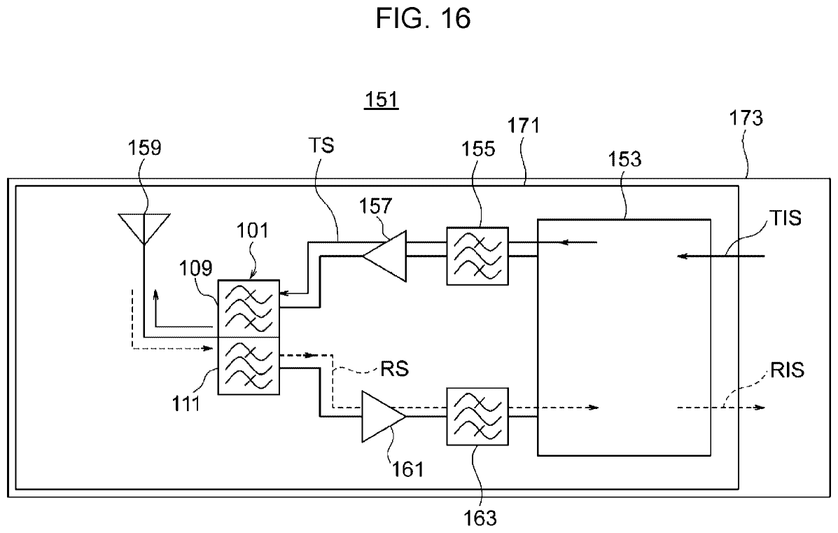

FIG. 16 is a block diagram illustrating the main components of a communication device 151 as an example use of the splitter 101 (an example of an acoustic wave element or a configuration including an acoustic wave element). The communication device 151 includes a module 171 and a housing 173 that houses the module 171. The module 171 performs wireless communication using radio waves and includes the splitter 101.

In the module 171, a transmission information signal TIS, which contains information to be transmitted, is modulated and raised in frequency (converted to a radio-frequency signal of a carrier frequency) by an RF—IC (radio-frequency integrated circuit) 153 (an example of an integrated circuit element) and becomes a transmission signal TS. Unwanted components outside a transmission passband are removed from the transmission signal TS by a bandpass filter 155, and the resulting transmission signal TS is then amplified by an amplifier 157 and input to the splitter 101 (transmission terminal 105). The splitter 101 (transmission filter 109) removes unwanted components outside the transmission passband from the input transmission signal TS, and then outputs the resulting transmission signal TS from the antenna terminal 103 to an antenna 159. The antenna 159 converts the input electrical signal (transmission signal TS) into a radio signal (radio waves) and transmits the radio signal.

In the module 171, a radio signal (radio waves) received by the antenna 159 is converted into an electrical signal (reception signal RS) by the antenna 159 and input to the splitter 101 (antenna terminal 103). The splitter 101 (reception filter 111) removes unwanted components outside a reception passband from the input reception signal RS and outputs the resulting reception signal RS from the reception terminals 107 to an amplifier 161. The output reception signal RS is amplified by the amplifier 161, and unwanted components outside the reception passband are removed by a bandpass filter 163. The reception signal RS is then reduced in frequency and demodulated by the RF—IC 153, and becomes a reception information signal RIS.

The transmission information signal TIS and the reception information signal RIS may be low-frequency signals (baseband signals) containing appropriate information, for example, analog or digitized audio signals. The radio-frequency signal passband may be set as appropriate, and in this embodiment, a relatively high frequency passband (for example, 5 GHz or higher) is also possible. The modulation method may be phase modulation, amplitude modulation, frequency modulation, or a combination of any two or more of these methods. Although the direct conversion method is illustrated as an example in FIG. 16, other types of circuit may be used as appropriate, for example, a double superheterodyne type circuit. FIG. 22 is a diagram schematically illustrating only the main components, and a low-pass filter, an isolator, and so on may be added at appropriate positions, and the positions of amplifiers and so on may be changed.

The module 171, for example, includes the components from the RF—IC 153 to the antenna 159 on the same circuit board. In other words, the acoustic wave element (part or all of the splitter 101) is modularized by being combined with other components. The acoustic wave element may be included in the communication device 151 without being modularized. The components illustrated as components of the module 171 may be positioned outside of the module or not housed in the housing 173. For example, the antenna 159 may be exposed outside the housing 173.

The technologies according to in the present disclosure are not limited to the above embodiments and variations, and may be implemented in various forms.

The composite substrate 3, which constitutes part of the acoustic wave element 1, is illustrated as a composite substrate. However, the composite substrate may be in a wafer state (not individualized) or in a state in which the conductor layer 5 is not provided. As is understood from the description of the embodiment, in the acoustic wave element 1, the x direction (the propagation direction of acoustic waves that are intended to be utilized. From another perspective, the direction in which the device is determined to be concave or not) may be specified based on the arrangement direction and/or extension direction of the multiple electrode fingers 27. On the other hand, in the composite substrate (wafer) prior to the conductor layer 5 being formed, the x direction may be specified based on orientation flat or specification documentation, for example.

### REFERENCE SIGNS

1 acoustic wave element, 3 composite substrate, 5 conductor layer, 7 support substrate, 9 low-acoustic-velocity film, 11 piezoelectric layer, 13 high-acoustic-velocity film, 19 IDT electrode.

1. A composite substrate comprising:
a piezoelectric layer; and
a low-acoustic-velocity film extending along a bottom surface of the piezoelectric layer and having a lower acoustic velocity than the piezoelectric layer,
wherein an inverse velocity plane of an acoustic wave propagating through the piezoelectric layer is concave.

2. An acoustic wave element comprising:
the composite substrate according to claim 1; and
a first IDT electrode including multiple electrode fingers arranged along a top surface of the piezoelectric layer.

3. The acoustic wave element according to claim 2,
wherein the piezoelectric layer and the low-acoustic-velocity film are directly stacked on each other from an acoustic point of view,
the piezoelectric layer is composed of rotated Y-cut X-propagation lithium tantalate single crystal,
the low-acoustic-velocity film is composed of silicon dioxide, and
when λ (μm) is twice a pitch of the multiple electrode fingers, a is a normalized thickness of the piezoelectric layer obtained by dividing a thickness (μm) of the piezoelectric layer by λ, b is a normalized thickness of the low-acoustic-velocity film obtained by dividing a thickness (μm) of the low-acoustic-velocity film by λ, and c° is an inclination angle of a Y axis to a normal of the piezoelectric layer, a, b, and c satisfy Equation (1) below.
$$- 3.36797 a + 2.582139 {a}^{2} - 1.02894 b + 1.487276 {b}^{2} - 0.02411 c + 0.000309 {c}^{2} + 0.432673 ab - 0.00517 ac + 0.000873 bc + 0.272652 < - 1. \qquad ( 1 )$$

4. The acoustic wave element according to claim 2,
wherein the composite substrate further includes a high-acoustic-velocity film located between the piezoelectric layer and the low-acoustic-velocity film and directly stacked on the piezoelectric layer and the low-acoustic-velocity film from an acoustic point of view,
the piezoelectric layer is composed of rotated Y-cut X-propagation lithium tantalate single crystal,
the low-acoustic-velocity film is composed of silicon dioxide,
the high-acoustic-velocity film is composed of aluminum oxide, and
when λ (μm) is twice a pitch of the multiple electrode fingers, a is a normalized thickness of the piezoelectric layer obtained by dividing a thickness (μm) of the piezoelectric layer by λ, b is a normalized thickness of the low-acoustic-velocity film obtained by dividing a thickness (μm) of the low-acoustic-velocity film by λ, c° is an inclination angle of a Y axis to a normal of the piezoelectric layer, and d is a normalized thickness of the high-acoustic-velocity film obtained by dividing a thickness (μm) of the high-acoustic-velocity film by λ, a, b, c, and d satisfy Equation (2) below.
$$- 3.26163 a - 0.30469 b - 0.02132 c + 3.843127 d + 2.196667 {a}^{2} + 0.960417 {b}^{2} + 0.00026 {c}^{2} - 7.75985 {d}^{2} - 0.01579 a b + 0.001339 ac - 1.26908 ad - 0.00246 bc - 0.8485 bd - 0.01067 cd + 0.151192 < - 1. \qquad ( 2 )$$

5. The acoustic wave element according to claim 2,
wherein the normalized thickness a of the piezoelectric layer is less than or equal to 1.0.

6. The acoustic wave element according to claim 2,
wherein the normalized thickness b of the low-acoustic-velocity film is less than or equal to 0.5.

7. The acoustic wave element according to claim 2,
wherein the first IDT electrode includes a first busbar and a second busbar that face each other in a direction intersecting an x direction when the piezoelectric layer is viewed in plan view,
multiple first electrode fingers extending from the first busbar toward the second busbar in a y direction perpendicular to the x direction, and
multiple second electrode fingers extending from the second busbar toward the first busbar in the y direction and arranged in an alternating manner with the multiple first electrode fingers in the x direction, and
a virtual line connecting tips of the multiple first electrode fingers and a virtual line connecting tips of the multiple second electrode fingers are inclined with respect to the x direction.

8. The acoustic wave element according to claim 2,
wherein the first IDT electrode includes a first busbar and a second busbar that face each other in a direction intersecting an x direction when the piezoelectric layer is viewed in plan view,
multiple first electrode fingers extending from the first busbar toward the second busbar in a y direction perpendicular to the x direction, and
multiple second electrode fingers extending from the second busbar toward the first busbar in the y direction and arranged in an alternating manner with the multiple first electrode fingers in the x direction,
a crossing region interposed between a virtual line connecting tips of the multiple first electrode fingers and a virtual line connecting tips of the multiple second electrode fingers includes two edge regions adjacent to the two virtual lines, and
a central region located more centrally in the crossing region than the two edge regions, and
an acoustic velocity of an acoustic wave excited by the first IDT electrode and propagating in the x direction through the piezoelectric layer is different in the central region and the two edge regions.

9. The acoustic wave element according to claim 2, further comprising:
a ladder filter including multiple IDT electrodes located on a top surface of the piezoelectric layer and connected to each other in a ladder configuration.

10. The acoustic wave element according to claim 2, further comprising:
a multi-mode filter including multiple IDT electrodes located on a top surface of the piezoelectric layer and arranged in an arrangement direction of the multiple electrode fingers.

11. A module comprising:
the acoustic wave element according to claim 2;
an antenna connected to the acoustic wave element; and
an integrated circuit element connected to the antenna via the acoustic wave element.

12. A communication device comprising:
the acoustic wave element according to claim 2;
an antenna connected to the acoustic wave element;
an integrated circuit element connected to the antenna via the acoustic wave element; and
a housing housing the acoustic wave element and the integrated circuit element.
